(19) United States
(12) Patent Application Publication
(10) Pub. No.: US 2026/0096481 A1
(43) Pub. Date: Apr. 2, 2026

(54) SEMICONDUCTOR PACKAGE STRUCTURE, FABRICATION METHOD AND MEMORY SYSTEM

(71) Applicant: Yangtze Memory Technologies Holding Co., Ltd., Wuhan (CN)

(72) Inventors: Xiaoxin Liu, Wuhan (CN); Zongliang Huo, Wuhan (CN)

(73) Assignee: Yangtze Memory Technologies Holding Co., Ltd., Wuhan (CN)

(21) Appl. No.: 19/055,695

(22) Filed: Feb. 18, 2025

(30) Foreign Application Priority Data
Sep. 30, 2024 (CN) 202411392115.X

(51) Int. Cl. H01L 25/07; H01L 23/00; H01L 23/48; H01L 23/538; H10B 80/00

(52) U.S. Cl. CPC H10W 90/00; H10W 20/20; H10W 70/611; H10W 90/401; H10B 80/00; H10W 72/072; H10W 72/241; H10W 80/312; H10W 80/327; H10W 90/26; H10W 90/297; H10W 90/722; H10W 90/792

(57) ABSTRACT

According to one aspect of the present disclosure, a semiconductor package structure is provided. The semiconductor package structure may include a first semiconductor chip and a second semiconductor chip stacked along a first direction and coupled with each other. The first semiconductor chip may include a first die and a second die that are bonded along the first direction. The first die may be coupled with the second die through a first bonding contact. The semiconductor package may include a first connection structure extending through the first die along the first direction. The semiconductor package structure may include a second connection structure extending through the second die along the first direction. The first bonding contact is located between the first connection structure and the second connection structure in the first direction. The first connection structure may be coupled with the second connection structure through the first bonding contact.

### CROSS-REFERENCE TO RELATED APPLICATIONS

This application claims the benefit of priority to Chinese Application No. 202411392115.X, filed on Sep. 30, 2024, which is incorporated herein by reference in its entirety.

### TECHNICAL FIELD

Examples of the present disclosure relate to the field of semiconductor technology, and particularly to a semiconductor package structure and a fabrication method thereof, and a memory system.

### BACKGROUND

Memory device is a storage apparatus for storing information in modern information technology. Some semiconductor memories, including some non-volatile memories and volatile memories, have gradually become mainstream products in the memory market as they have high storage density, controllable production costs, appropriate programming and erasing speeds, and data retention property. However, with the increasingly high requirements on the computing power and high bandwidth memory devices, there is still a lot of room for improvement in the package of memory device.

### SUMMARY

According to one aspect of the present disclosure, a semiconductor package structure is provided. The semiconductor package structure may include a first semiconductor chip and a second semiconductor chip stacked along a first direction and coupled with each other. The first semiconductor chip may include a first die and a second die that are bonded along the first direction. The first die may be coupled with the second die through a first bonding contact. The semiconductor package may include a first connection structure extending through the first die along the first direction. The semiconductor package structure may include a second connection structure extending through the second die along the first direction. The first bonding contact is located between the first connection structure and the second connection structure in the first direction. The first connection structure may be coupled with the second connection structure through the first bonding contact.

In some implementations, the semiconductor package structure may include a bump that is located at an end of the second connection structure away from the first connection structure and is located between the second connection structure and the second semiconductor chip. In some implementations, the first semiconductor chip and the second semiconductor chip may be coupled at least through the bump and the second connection structure.

In some implementations, the first semiconductor chip may be bonded with the second semiconductor chip. In some implementations, the first semiconductor chip and the second semiconductor chip may be coupled through a second bonding contact. In some implementations, the second bonding contact may be located at an end of the second connection structure away from the first connection structure and is coupled with the second connection structure.

In some implementations, the second semiconductor chip may include a third die and a fourth die that are bonded along the first direction. In some implementations, the third die may be located between the second die and the fourth die, and the third die and the fourth die may be coupled through a third bonding contact. In some implementations, the second semiconductor chip may include a third connection structure extending through the third die along the first direction. In some implementations, the third connection structure may be located between the second connection structure and the third bonding contact and may be coupled with the second connection structure and the third bonding contact.

In some implementations, the second semiconductor chip may further include a fourth connection structure extending through the fourth die along the first direction. In some implementations, the fourth connection structure may be located on a side of the third bonding contact away from the third connection structure and may be coupled with the third bonding contact.

In some implementations, the first die may include a transistor including a first active region, a second active region, and a gate layer. In some implementations, the first die may include a bit line coupled with the first active region. In some implementations, the first die may include a capacitor structure coupled with the second active region. In some implementations, the first die may include a peripheral circuit coupled with the bit line and the gate layer.

In some implementations, the first die may include a transistor including a first active region, a second active region, and a gate layer. In some implementations, a bit line coupled with the first active region. In some implementations, a capacitor structure coupled with the second active region. In some implementations, the second die may include a peripheral circuit coupled with the bit line and the gate layer.

In some implementations, the transistor may include a semiconductor pillar extending along the first direction. In some implementations, the first active region and the second active may be located at two opposite ends of the semiconductor pillar in the first direction. In some implementations, the gate layer may extend along a direction intersecting the first direction, and covers part of a sidewall of the semiconductor pillar.

In some implementations, the semiconductor package structure may include a base semiconductor chip located on a side of the first semiconductor chip away from the second semiconductor chip and may include a logic control circuit. In some implementations, an end of the first connection structure away from the second connection structure may be coupled with the base semiconductor chip.

In some implementations, the semiconductor package structure may include an interposer substrate located on a side of the base semiconductor chip away from the first semiconductor chip. In some implementations, the base semiconductor chip may be coupled with the interposer substrate.

According to another aspect of the present disclosure, a method of fabricating a semiconductor package structure is provided. The method may include forming a first connection structure extending through a first die, and forming a first bonding sub-layer having a first bonding sub-contact at a first end of the first connection structure along a first direction. The first end of the first connection structure may be coupled with the first bonding sub-contact. The method may include forming a second connection structure extending through a second die, and forming a second bonding sub-layer having a second bonding sub-contact at a first end of the second connection structure along the first direction. The first end of the second connection structure may be coupled with the second bonding sub-contact. The method may include bonding the first bonding sub-layer and the second bonding sub-layer to form a first semiconductor chip. The first bonding sub-layer and the second bonding sub-layer may be bonded to form a first bonding layer. The first bonding sub-contact and the second bonding sub-contact may be bonded to form a first bonding contact. The method may include stacking a second semiconductor chip on the first semiconductor chip. The second semiconductor chip may be coupled with the first semiconductor chip.

In some implementations, the method may include forming a bump at an end of the second connection structure away from the first connection structure. In some implementations, the bump may be coupled with the second connection structure. In some implementations, the method may include stacking the second semiconductor chip on the bump. In some implementations, the second semiconductor chip may be coupled with the first semiconductor chip through the bump.

In some implementations, the method may include bonding the second semiconductor chip on a side of the second connection structure away from the first connection structure. In some implementations, the first semiconductor chip may be coupled with the second semiconductor chip through a second bonding contact, and the second bonding contact may be located at an end of the second connection structure away from the first connection structure and is coupled with the second connection structure.

In some implementations, a first wafer may include the first die, the first end of the first connection structure may be exposed from a surface of the first wafer, and a second end of the first connection structure opposite to the first end in the first direction may be located in the first wafer. In some implementations, a second wafer may include the second die, the first end of the second connection structure may be exposed from a surface of the second wafer, and a second end of the second connection structure along the first direction may be located in the second wafer. In some implementations, forming the first semiconductor chip may include forming the first bonding sub-layer on a side of the first wafer exposing the first connection structure. In some implementations, forming the first semiconductor chip may include forming the second bonding sub-layer on a side of the second wafer exposing the second connection structure. In some implementations, forming the first semiconductor chip may include bonding the first bonding sub-layer and the second bonding sub-layer. In some implementations, the first bonding sub-contact may be coupled with the second bonding sub-contact.

In some implementations, forming the first semiconductor chip may further include thinning the second wafer to expose the second end of the second connection structure. In some implementations, forming the first semiconductor chip may further include forming a first bump on the second end of the second connection structure. In some implementations, the first bump may be coupled with the second end of the second connection structure.

In some implementations, forming the first semiconductor chip may further include thinning the first wafer to expose the second end of the first connection structure. In some implementations, forming the first semiconductor chip may further include forming a second bump on the second end of the first connection structure. In some implementations, the second bump may be coupled with the second end of the first connection structure. In some implementations, forming the first semiconductor chip may further include cutting a bonded structure of the first wafer and the second wafer to obtain a plurality of first semiconductor chips.

In some implementations, forming the second semiconductor chip may include forming a third connection structure extending through a third die along the first direction. In some implementations, forming the second semiconductor chip may include bonding the third die and a fourth die along the first direction to form the second semiconductor chip. In some implementations, the third die may be located between the second die and the fourth die and may be coupled with the fourth die through a third bonding contact, and the third connection structure may be located between the second connection structure and the third bonding contact and may be coupled with the second connection structure and the third bonding contact.

In some implementations, the method may include forming a fourth connection structure extending through the fourth die along the first direction. In some implementations, the fourth connection structure may be coupled with the third connection structure through the third bonding contact.

In some implementations, forming the first die may include forming a transistor including a first active region, a second active region, and a gate layer. In some implementations, forming the first die may include forming a bit line coupled with the first active region. In some implementations, forming the first die may include forming a capacitor structure coupled with the second active region. In some implementations, forming the first die may include forming a peripheral circuit coupled with the bit line and the gate layer.

In some implementations, forming the first die may include forming a transistor including a first active region, a second active region, and a gate layer. In some implementations, forming the first die may include forming a bit line coupled with the first active region. In some implementations, forming the first die may include forming a capacitor structure coupled with the second active region. In some implementations, forming the second die may include forming a peripheral circuit coupled with the bit line and the gate layer.

In some implementations, the method may include disposing the first semiconductor chip on a base semiconductor chip that includes a logic control circuit. In some implementations, an end of the first connection structure away from the second connection structure may be coupled with the base semiconductor chip.

In some implementations, the method may include disposing the base semiconductor chip on an interposer substrate. In some implementations, the base semiconductor chip may be coupled with the interposer substrate.

According to a further aspect of the present disclosure, a memory system is provided. The memory system may include a semiconductor package structure. The semiconductor package structure may include a first semiconductor chip and a second semiconductor chip stacked along a first direction and coupled with each other. The first semiconductor chip may include a first die and a second die that are bonded along the first direction. The first die may be coupled with the second die through a first bonding contact. The semiconductor package structure may include a first connection structure extending through the first die along the first direction. The semiconductor package structure may include a second connection structure extending through the second die along the first direction. The first bonding contact may be located between the first connection structure and the second connection structure in the first direction. The first connection structure may be coupled with the second connection structure through the first bonding contact.

The examples of the present disclosure provide a semiconductor package structure. A first semiconductor chip includes a first die and a second die that are bonded along a first direction, and the first die is coupled with the second die through a first bonding contact. A first connection structure extends through the first die along the first direction, and a second connection structure extends through the second die along the first direction. The first bonding contact is located between the first connection structure and the second connection structure in the first direction. The first connection structure and the second connection structure are coupled through the first bonding contact to enable electrical signal interconnection between the first die and the second die, which can increase the device integration level of the first semiconductor chip. The first semiconductor chip and the second semiconductor chip may achieve electrical signal interconnection through bonding or bump coupling, which increases the integration level of the semiconductor package structure and achieves package of various types of chips. Compared with a package scheme where a plurality of dies are stacked sequentially, in the examples of the present disclosure, the first die is bonded with the second die to constitute the first semiconductor chip, and the first semiconductor chip and other semiconductor chips are packaged in stack, which can reduce the process difficulty caused by stacking a plurality of dies, and improve the package yield and device stability.

### BRIEF DESCRIPTION OF THE DRAWINGS

FIG. 1 is a schematic diagram illustrating a semiconductor package structure according to an example;

FIG. 2 is a schematic diagram illustrating a memory array according to an example;

FIGS. 3 to 10 are schematic diagrams illustrating an example semiconductor package structure according to examples of the present disclosure;

FIGS. 11 and 12 are schematic diagrams illustrating an example system according to examples of the present disclosure;

FIG. 13 is a flow diagram illustrating an example fabrication method of a semiconductor package structure according to examples of the present disclosure; and

FIGS. 14 to 22 are schematic diagrams illustrating fabrication of a semiconductor package structure according to examples of the present disclosure.

### DETAILED DESCRIPTION

Example implementations disclosed in the present disclosure will be described below in more details with reference to the drawings. Although the example implementations of the present disclosure are shown in the drawings, it is to be understood that the present disclosure may be implemented in various forms and should not be limited by the specific implementations set forth herein. Rather, these implementations are provided for a more thorough understanding of the present disclosure, and to fully convey the scope disclosed by the present disclosure to those skilled in the art.

In the following description, numerous specific details are given in order to provide a more thorough understanding of the present disclosure. However, it is apparent to those skilled in the art that the present disclosure may be practiced without one or more of these details. In other examples, in order to avoid confusing with the present disclosure, some technical features well-known in the art are not described; that is, not all features of actual examples are described here, and well-known functions and structures are not described in detail.

It is to be understood that when an element or a layer is referred to as being “on”, “adjacent to”, “connected to”, or “coupled to” other elements or layers, it may be directly on, adjacent to, connected to, or coupled to the other elements or layers, or intervening elements or layers may be present. In contrast, when an element is referred to as being “directly on”, “immediately adjacent to”, “directly connected to”, or “directly coupled to” other elements or layers, no intervening elements or layers are present. It is to be understood that, although the terms first, second, third, etc. may be used to describe various elements, components, areas, layers, and/or portions, these elements, components, areas, layers, and/or portions should not be limited by these terms. These terms are only used to distinguish one element, component, area, layer or portion from another element, component, area, layer or portion. Thus, a first element, component, area, layer or portion discussed below may be denoted as a second element, component, area, layer or portion, without departing from the teachings of the present disclosure. When the second element, component, area, layer or portion is discussed, it does not mean that the first element, component, area, layer or portion is necessarily present in the present disclosure.

The spatially relative terms, such as “beneath”, “below”, “lower”, “under”, “over”, “upper”, and the like, may be used herein for ease of description to describe one element or feature's relationship to other elements or features as illustrated in the drawings. It should be understood that in addition to orientations shown in the drawings, the spatial relationship terms are intended to further include the different orientations of a device in use and operation. For example, if a device in the drawings is turned over, then the elements or the features described as “below” or “under” or “beneath” another element or feature may be oriented “on” the other element or feature. Therefore, the example terms “below” and “beneath” may comprise both upper and lower orientations. The device may be orientated otherwise (rotated by 90 degrees or in other orientations), and the spatially descriptive terms used herein are interpreted accordingly.

The terms used herein are only intended to describe the specific examples, and are not used as limitations of the present disclosure. As used herein, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more of other features, integers, steps, operations, elements, components, and/or groups. As used herein, the term “and/or”comprises any or all combinations of the listed relevant items.

It is to be understood that references to “some examples” or “an example” throughout this specification mean that particular features, structures, or characteristics related to the example(s) are comprised in at least one example of the present disclosure. Therefore, “in some examples” or “in an example” presented throughout this specification does not necessarily refer to the same example. In addition, these specific features, structures or characteristics may be combined in one or more examples in any suitable manner. It is to be understood that, in various examples of the present disclosure, sequence numbers of the above processes do not indicate an execution sequence, and an execution sequence of various processes shall be determined by functionalities and intrinsic logics thereof, and shall constitute no limitation on an implementation process of the examples of the present disclosure.

With the recent rapid development and extensive expansion of artificial intelligence, machine learning, high-performance computing, graphics, vehicle and network applications, there is a growing demand for a variety of integrated circuits with high performance, large computing power or high storage density, the planar integration of integrated circuits occupies more area, and the three-dimensional integration or three-dimensional packaging of the integrated circuits can achieve higher integration density.

A three-dimensional integrated circuit is packaged or manufactured by stacking semiconductor chips with electronic circuitries formed therein or thereon. These stacked semiconductor chips may be provided with vertical interconnects, and may be interconnected by through silicon vias (TSVs) to constitute a circuit structure with electrical functions. For example, multiple memory chips may be stacked together and interconnected by through silicon vias to obtain a high-bandwidth memory (HBM), which shortens the interconnect length between the chips and improves the performance of the memory product.

A semiconductor package structure (or a semiconductor structure) is provided according to examples of the present disclosure. The semiconductor package structure may include a structure where a plurality of semiconductor chips are stacked together and bonded in a thickness direction or a vertical direction to achieve a semiconductor structure with more electrical functions and higher integration density and reduced horizontal footprint. The semiconductor chip mentioned in the examples of the present disclosure may refer to a semiconductor wafer, including, but not limited to, a silicon chip, a germanium chip, a silicon carbide chip, and other semiconductor chips fabricated on the basis of a semiconductor wafer and having electrical, optical, acoustic, and other functions. The semiconductor chip or the semiconductor structure may be a structure cut from the semiconductor wafer, and the semiconductor chip may have electronic circuitry formed therein or thereon. The semiconductor chip may include coupling between a plurality of semiconductor sub-structures. The coupling may include, e.g., two-dimensional integration coupling in a horizontal direction or three-dimensional bonding coupling in a vertical direction. Examples of the semiconductor chip include a memory logic chip, a memory core chip, a central processing unit chip, and other electronic device chips.

The semiconductor structure, the semiconductor chip, and the die described above in the examples of the present disclosure are merely schematic and are merely illustrative of a hierarchical logical division with an inclusive relationship for illustrative purposes. As such, there may be other division methods in actual implementations, to which the present disclosure has no limitations. In some other examples, for example, a plurality of structures, chips, units or assemblies may be combined or may be integrated into another system, or some features may be omitted or not be included.

According to some aspects of examples of the present disclosure, a semiconductor package structure 10 includes a plurality of semiconductor chips stacked along a first direction. The semiconductor chips are coupled through a first bump 131; at least the semiconductor chips under the topmost semiconductor chip may have connection structures that extend through their corresponding semiconductor chips in a z direction; the first bump 131 is located between two adjacent connection structures in the z direction to achieve electrical signal interconnection; and the z direction may be a thickness direction of the device, or a vertical direction. The z direction may be a first direction, an x direction may be a second direction, a y direction may be a third direction, the x direction may be perpendicular to or intersect the y direction, and the z direction is perpendicular to or intersects an xy plane.

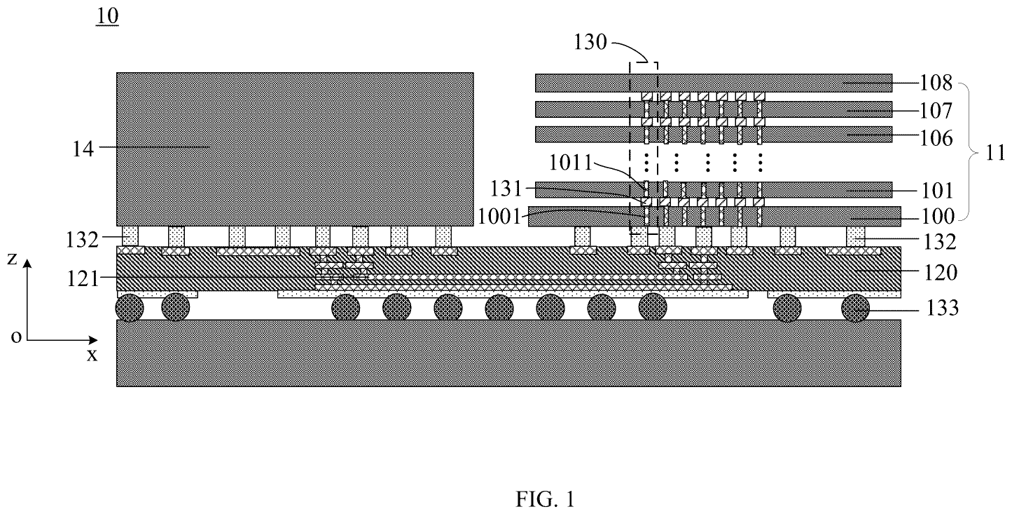

As illustrated in FIG. 1, the semiconductor package structure 10 may include a package sub-structure 11 that may include a base semiconductor chip 100, and a plurality of semiconductor chips stacked sequentially on the base semiconductor chip 100. One semiconductor chip may include one die, for example, a first die 101, . . . , a sixth die 106, a seventh die 107, an eighth die 108 or more dies as shown in FIG. 1. One semiconductor chip may include a connection structure extending through each die and extending along the z direction, for example, a base connection structure 1001 extending through the base semiconductor chip 100, a first connection structure 1011 extending through the first die 101, and a second connection structure extending through the second die 102, and a first bump 131 located and coupled between the base connection structure 1001 and the first connection structure 1011.

There may be no other dies disposed over the eighth die 108, and a connection structure extending through the eighth die 108 may be or may be not disposed. The first bump 131 is disposed between adjacent dies for electrical signal interconnection, and may be located between adjacent connection structures in the z direction to achieve electrical signal interconnection between each die and the base semiconductor chip 100. When the eighth die 108 is not provided with a connection structure, an electrical signal of the eighth die 108 may be led out to the first bump 131 through a routing layer, and electrical signal interconnection with other chips is achieved through the first bump 131. The connection structure may be a through silicon via (TSV) and may include a conductive plug, a conductive channel or other structure. The bump may include, but is not limited to, a contact, a conductive ball, a solder ball or other structure.

With reference to FIG. 1, the connection structure extending through each die and the first bump 131 coupling with the connection structure are stacked and coupled sequentially in the z direction to constitute a conductive channel 130 along the z direction, which may achieve electrical signal interaction between the base semiconductor chip 100 and each die, including control signal communication, data access, power transmission, etc. Different conductive channels 130 may provide a power channel and a data bus channel.

The base semiconductor chip 100 may include a logic control circuit, and may access and control any die through the conductive channel 130. Any die may also achieve electrical signal interaction with the base semiconductor chip 100 through the conductive channel 130. The die may include, but is not limited to, a logic chip of a logic control circuit, and a memory chip such as DRAM, NAND, SRAM, etc. For example, the die may be a DRAM chip to be applied to an HBM package scheme, and may be applicable to a double-data-rate synchronous dynamic random access memory in accordance with a DDR4 memory specification and a DDR5 memory specification, and a low-power double-data-rate synchronous dynamic random access memory in accordance with a LPDDR5 memory specification.

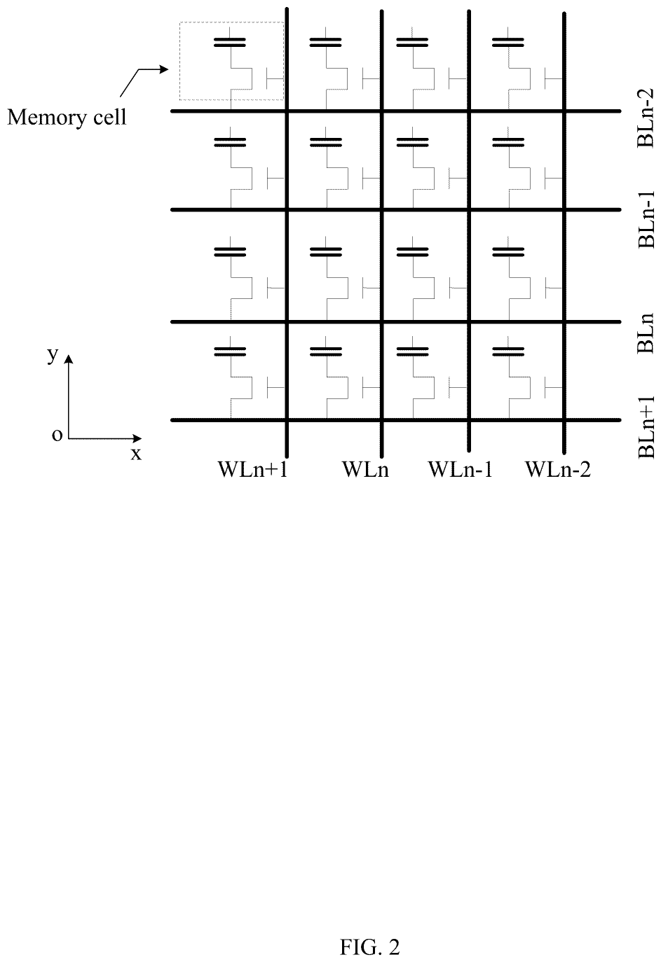

The die in FIG. 1 may include memory cells to constitute a memory device, including, but not limited to, DRAM, NAND and SRAM memory devices. The die in FIG. 1 may be a DRAM memory device or part of a DRAM memory device. In the DRAM, a memory array may be arranged in rows and columns, such that the memory cell may be addressed by specifying a row and a column of an array to which the memory cell belongs. The memory array includes a plurality of word lines corresponding to the rows and a plurality of bit lines corresponding to the columns, where the word lines intersect the bit lines. A memory cell at an intersection of a selected word line and a selected bit line is selected to perform a read, write or refresh operation. As illustrated in FIG. 2, the memory array may include a plurality of word lines WLn, WLn+1, WLn−1 and WLn−2 and a plurality of bit lines BLn, BLn+1, BLn−1 and BLn−2, and the word lines intersect the bit lines. The memory cell in the memory array may include a capacitor and a transistor, and one memory cell may include one transistor and one capacitor. The word line may be also a gate layer or other conductive structure which serves as a gate of the transistor. One controlled terminal (source) of the transistor is coupled with one electrode of the capacitor, the other controlled terminal (drain) of the transistor is coupled with the bit line, and the other electrode of the capacitor may be grounded or applied with other voltages (e.g., Vcc/2). As shown in FIG. 1, the memory cell array is arranged in an array of x columns and y rows, and the rows and the columns may be or may be not perpendicular. The z direction is a vertical direction or a thickness direction of a device and may be a first direction in the examples of the present disclosure, and the xy plane intersects and is perpendicular to the z direction. An extending direction of the bit line or the column may be parallel to the y direction or have an included angle with the y direction. An extending direction of the word line or the row may be parallel to the x direction or have an included angle with the x direction. An orthographic projection of the word line on the xy plane and an orthographic projection of the bit line on the xy plane may be perpendicular or may not be perpendicular but have a certain included angle.

In some examples, during a read or write operation, a corresponding word line may be selected by using a word line select signal, and a corresponding bit line may be selected according to a column select signal. When both the word line and the bit line are selected, a selected memory cell may be located. At this point, the transistor of the selected memory cell is turned on due to an operation voltage applied to the word line, so that a read, write, or refresh operation may be performed on the selected memory cell. In some examples, the capacitor may be replaced with other storage structures, including, but not limited to, a phase change storage structure, a resistive storage structure, or a magnetic storage structure, etc.

In some examples, the capacitor represents logic 1 and 0 through the amount of charges stored therein or a magnitude of voltage difference between two ends of the capacitor. A voltage signal on the word line is applied to the gate to control the on or off of the transistor, thereby achieving selection and unselection of the capacitor, such that, data information stored in the capacitor is read through the bit line, or data is written to the capacitor through the bit line for storage.

In some examples, the DRAM memory device further includes a peripheral circuit coupled with the memory array of FIG. 2. In an example, the peripheral circuit may include, but is not limited to, a sense amplifier circuit, a row decoding circuit, a column decoding circuit, a voltage generation circuit, etc. The sense amplifier circuit is coupled with the bit line, and may be configured to capture weak voltage fluctuation on the bit line, and recover a capacitor voltage of the memory cell locally according to the voltage fluctuation. The sense amplifier circuit may include a latch, which may latch the value of the recovered capacitor voltage, such that information stored in the memory cell is transferred from the capacitor to the amplifier circuit. The sense amplifier circuit may include a differential sense amplifier circuit that is coupled with two bit lines and operates by using a selected bit line and a complementary bit line serving as a reference line, to detect and amplify a voltage difference on a pair of bit lines. The row decoding circuit is configured to perform row addressing on the memory array and apply an operation voltage to the word line. The column decoding circuit is configured to perform column addressing on the memory array and apply or receive a bit line voltage. The voltage generation circuit generates high and low voltages required for each device.

In some examples, the peripheral circuit may include a CMOS structure or a CMOS circuit, including a digital or analog circuit composed of transistors, and is configured to control or supply power to the memory array. The increase in device integration level of the peripheral circuit is conducive to increasing the integration level of the overall memory device, and the improvement in device stability of the peripheral circuit is conducive to improving the operation stability of the memory device.

In some examples, with reference to FIG. 1, the semiconductor package structure 10 further includes an interposer substrate 120 and a processor chip 14. The processor chip 14 and the package sub-structure 11 are located on the interposer substrate 120. The processor chip and the package sub-structure 11 may be coupled with a routing layer 121 or a redistribution layer of the interposer substrate 120 through a second bump 132. The interposer substrate 120 provides power supply transition and data or communication signal transition for the processor chip 14 and the package sub-structure 11. Other redistribution layers or interconnection structures are further disposed in the interposer substrate 120, and a side of the interposer substrate 120 away from the package sub-structure 11 in the z direction has contacts for coupling with an integrated circuit on an external PCB board. The interposer substrate 120 may include, but is not limited to, a silicon interposer board, or other substrates and materials applied to the package. The interposer substrate 120 may be coupled with the external PCB board through a third bump 133. In an example, the interposer substrate 120 transfers power of the PCB board to provide power to the package sub-structure 11 and other chips on the interposer substrate 120, and the interposer substrate 120 transfers data and communication signals of the PCB board to achieve data transmission and communication interaction between the package sub-structure 11 and the PCB board.

The interposer substrate 120 provides electrical signal interaction of the processor chip 14 and the package sub-structure 11, and the processor chip 14 may access the package sub-structure 11 through the routing layer 121 of the interposer substrate 120, e.g., sending a request to the base semiconductor chip 100. The base semiconductor chip 100 accesses the die to acquire data and sends the data to the processor chip 14. A connection structure, e.g., the base connection structure 1001 of the base semiconductor chip 100 may be coupled with the interposer substrate 120 through a second bump 132, and the interposer substrate 120 may provide power and information interaction for the package sub-structure 11. In an example, the interposer substrate 120 may transmit power and information to the base semiconductor chip 100, and the base semiconductor chip 100 sends the power and information to a target die through the conductive channel 130, where the information may be from the processor chip 14.

In some examples, the first die 101, the second die, the third die to the eighth die 108 or even more dies are stacked and coupled sequentially. After the stacked dies reach a large number, for example, after seven dies have been stacked on the base semiconductor chip 100, the height of film layers becomes large, and stacking a further 8^{th} die may cause the stacked seven dies to collapse due to cracking of the bump or the package material (such as a plastic package film, etc.) caused by the large height and stress of layers, which may reduce the package yield. In view of this, some aspects of examples of the present disclosure provide a semiconductor package structure 10 and a fabrication method (or a package method). A plurality of dies are hybrid-bonded to constitute a semiconductor chip, and then a plurality of semiconductor chips are stacked to form a package structure, which can reduce the process difficulty caused by sequential stacking of the plurality of dies and improve the package yield and device stability.

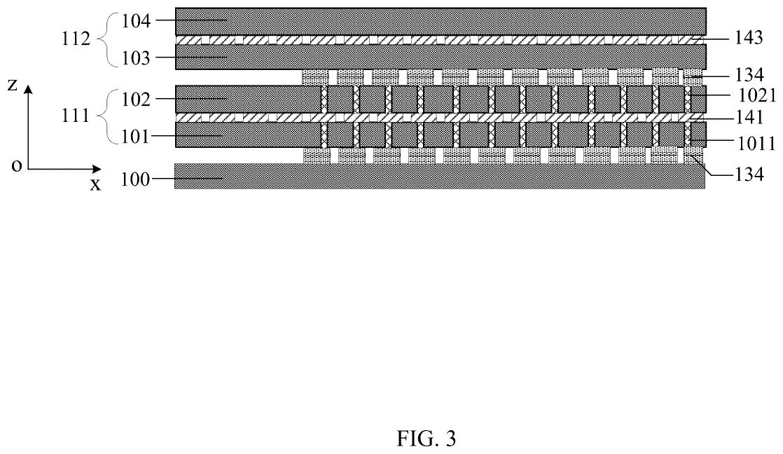

According to some aspects of the examples of the present disclosure, FIG. 3 provides a semiconductor package structure 10 including: a first semiconductor chip 111 and a second semiconductor chip 112 stacked along a first direction (the z direction) and coupled with each other, where the first semiconductor chip 111 includes a first die 101 and a second die 102 that are bonded along the z direction, and the first die 101 is coupled with the second die 102 through a plurality of first bonding contacts 141 of a first bonding layer; a first connection structure 1011 extending through the first die 101 along the z direction; and a second connection structure 1021 extending through the second die 102 along the z direction, where the first bonding contact 141 is located between the first connection structure 1011 and the second connection structure 1021 in the z direction, and the first connection structure 1011 is coupled with the second connection structure 1021 through the first bonding contact 141.

In FIG. 3, two coupled semiconductor chips are shown as an example. Additional semiconductor chips may be stacked in the z direction, and the examples of the present disclosure do not limit the number and type of the semiconductor chips. The semiconductor chips may be coupled through a bump 134, or coupled by hybrid bonding, and the bump 134 may include a solder ball, a conductive ball, a conductive contact, or other structure. The semiconductor chip may include a plurality of dies that are bonded in the z direction, or a plurality of dies that are disposed in the x or y direction, and the dies may be semiconductor structures or semiconductor devices cut from a wafer.

The first semiconductor chip 111 and the second semiconductor chip 112 may be coupled through a bonding layer having a plurality of bonding contacts. The bonding layer includes a dielectric layer and the bonding contacts embedded in the dielectric layer or extending through the dielectric layer that are coupled for electrical signal interconnection. The bump 134 may be disposed between the first semiconductor chip 111 and the second semiconductor chip 112, which enables electrical signal interaction through the bump 134.

In FIG. 3, the first semiconductor chip 111 may include a first die 101 and a second die 102 that are bonded in the z direction, and the second die 102 may be located over the first die 101 in the figure. Prior to bonding, the first die 101 and the second die 102 are provided, and have a first bonding sub-layer and a second bonding sub-layer respectively. The first bonding sub-layer may include a plurality of first bonding sub-contacts and a first dielectric sub-layer, the second bonding sub-layer includes a plurality of second bonding sub-contacts and a second dielectric sub-layer, and the bonding contact may include, but is not limited to, a pad, a conductive plug, or other structure. The first bonding sub-contact may be coupled with an interconnect layer or a routing layer of the first die 101 to lead out an electrical signal of the first die 101 to the bonding layer, and the second bonding sub-contact may be coupled with an interconnect layer or a routing layer of the second die 102 to lead out an electrical signal of the second die 102 to the bonding layer. The first bonding sub-layer is bonded with the second bonding sub-layer, and an interface where two surfaces to be bonded are in contact is a bonding interface. The first bonding sub-contact and the second bonding sub-contact are in contact, bonded and coupled at the bonding interface to achieve electrical signal interconnection between the first die 101 and the second die 102. The first bonding sub-contact and the second bonding sub-contact may not have a physical boundary after bonding, and the first bonding sub-contact and the second bonding sub-contact may be regarded as a first bonding contact 141. The first dielectric sub-layer and the second dielectric sub-layer may not have a physical boundary after thermal compression bonding, and the first dielectric sub-layer and the second dielectric sub-layer may may be regarded as a first dielectric layer that constitutes or provides the bonding interface, and the first bonding contact 141 extends through the bonding interface. A portion of the first bonding contact 141 in the first die 101 is the first bonding sub-contact before bonding, and a portion of the first bonding contact 141 in the second die 102 is the second bonding sub-contact before bonding.

With reference to FIG. 3, the first die 101 has the first connection structure 1011 extending along the z direction. The first connection structure 1011 extends through the first die 101 along the z direction, and the first connection structure 1011 may be coupled with the interconnect layer in the first die 101 to lead out the electrical signal of the first die 101. The interconnect layer may include a plurality of routing layers that are stacked together, and the adjacent routing layers are coupled through a conductive plug. The second connection structure 1021 extends through the second die 102 along the z direction and is coupled with the routing layer of the second die 102 to lead out the electrical signal of the second die 102. In the z direction, the first bonding contact 141 is located between the first connection structure 1011 and the second connection structure 1021. The first connection structure 1011 and the second connection structure 1021 are coupled through the first bonding contact 141. The first connection structure 1011, the first bonding contact 141, and the second connection structure 1021 may constitute a conductive channel extending along the z direction. The first die 101 and the second die 102 may achieve electrical signal interconnection through the conductive channel. In an example, the first bonding sub-contact of the first bonding contact 141 is coupled with the first connection structure 1011, and the second bonding sub-contact of the first bonding contact 141 is coupled with the second connection structure 1021. The first connection structure 1011 and the second connection structure 1021 are coupled to achieve electrical signal interaction after the first bonding sub-contact is bonded with the second bonding sub-contact. The second semiconductor chip 112 is disposed over the second die 102 of the first semiconductor chip 111, and the second semiconductor chip 112 may include a conductive contact that may be coupled with the second connection structure 1021 of the second die 102 through the bump 134 or hybrid bonding.

In some examples, the semiconductor package structure 10 includes the bump 134 that is located at an end of the second connection structure 1021 away from the first connection structure 1011 and is located between the second connection structure 1021 and the second semiconductor chip 112, where the first semiconductor chip 111 is coupled with the second semiconductor chip 112 at least through the bump 134 and the second connection structure 1021.

With reference to FIG. 3, the first die 101, the second die 102, and the second semiconductor chip 112 are stacked sequentially in the z direction, the first die 101 and the second die 102 are hybrid-bonded to constitute the first semiconductor chip 111, and the bump 134 may be disposed between the second semiconductor chip 112 and the second die 102 to couple the second connection structure 1021 and the second semiconductor chip 112. The first connection structure 1011, the second connection structure 1021, and the bump 134 may constitute a conductive channel or part of a conductive channel in the z direction, thereby forming electrical signal interconnection of the first semiconductor chip 111 and the second semiconductor chip 112, including, but not limited to, power supply, data transmission and control signal interaction.

In some examples, with reference to FIG. 3, one first connection structure 1011, one first bonding contact 141, one second connection structure 1021, and one bump 134 correspond to one another; one first connection structure 1011 is correspondingly coupled with one second connection structure 1021 through one bonding contact; and the second connection structure 1021 may be correspondingly coupled with one bump 134. It may be understood that some first connection structures 1011 and the first bonding contacts 141 may have an offset in the x/y direction or even are not coupled, and the second connection structure 1021 and the bump 134 may have an offset in the x/y direction and even are not coupled.

In an example, composition materials of the connection structure and the bump 134 may include, but are not limited to, a conductive material such as tungsten, gold, silver, platinum, copper, aluminum, titanium, tin or nickel, etc. The connection structure may further include a conductive material such as doped polysilicon, etc.

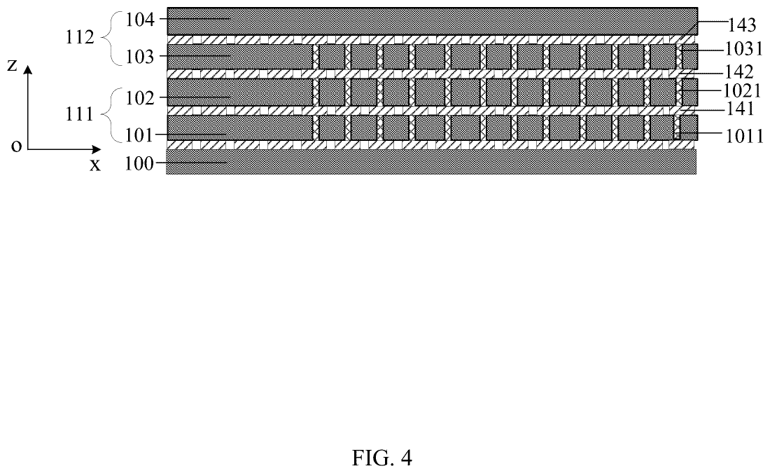

In some examples, with reference to FIG. 4, the first semiconductor chip 111 is bonded with the second semiconductor chip 112, the first semiconductor chip 111, and the second semiconductor chip 112 are coupled through a second bonding contact 142, and the second bonding contact 142 is located at an end of the second connection structure 1021 away from the first connection structure 1011 and is coupled with the second connection structure 1021.

Similar to the formation or bonding process of the first bonding contact 141, the first semiconductor chip 111 includes a third bonding sub-layer having a plurality of third bonding sub-contacts. The third bonding sub-contact is located at an end of the second connection structure 1021 away from the first connection structure 1011, and is coupled with the second connection structure 1021. The second semiconductor chip 112 has a fourth bonding sub-layer including a plurality of fourth bonding sub-contacts. The third bonding sub-layer and the fourth bonding sub-layer may not have a physical boundary after bonding and form a second bonding layer, and the third bonding sub-contact and the fourth bonding sub-contact may not have a physical boundary after bonding and form the second bonding contact 142. With the second die 102 of the first semiconductor chip 111 as an example, two opposite sides of the second die 102 in the z direction have a second bonding sub-contact 1412 and a third bonding contact 143 that are configured to be bonded and coupled with the first bonding sub-contact of the first die 101 and the fourth bonding sub-contact of the second semiconductor chip 112 respectively. The first connection structure 1011, the first bonding contact 141, the second connection structure 1021 and the second bonding contact 142 constitute a conductive channel extending along the z direction for forming electrical signal interconnection of the first semiconductor chip 111 and the second semiconductor chip 112.

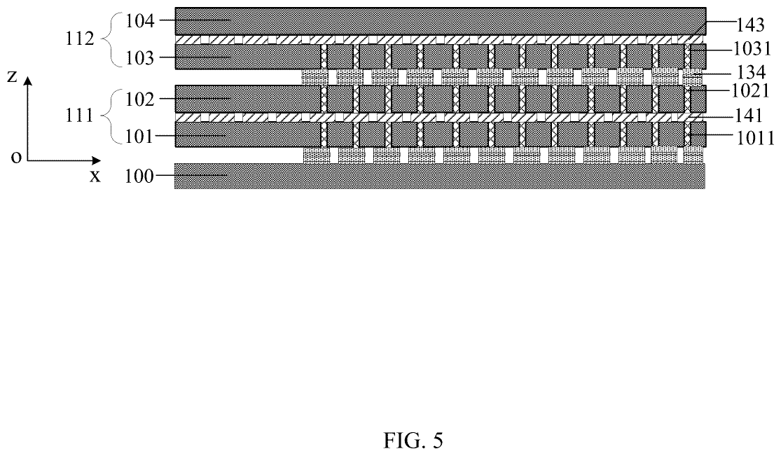

In some examples, with reference to FIGS. 4 and 5, the second semiconductor chip 112 includes a third die 103 and a fourth die 104 that are bonded along the z direction, where the third die 103 is located between the second die 102 and the fourth die 104, and is coupled with the fourth die 104 through a third bonding contact 143; and the second semiconductor chip 112 includes a third connection structure 1031 that is located between the second connection structure 1021 and the third bonding contact 143, and is coupled with the second connection structure 1021 and the third bonding contact 143. There may be no other semiconductor chip stacked over the second semiconductor chip 112, and the fourth die 104 may have or may not have a connection structure.

The second semiconductor chip 112 and the first semiconductor chip 111 in FIG. 4 may be coupled through the second bonding contact 142; and the first connection structure 1011, the first bonding contact 141, the second connection structure 1021, the second bonding contact 142, the third connection structure 1031 and the third bonding contact 143 constitute a conductive channel or part of a conductive channel extending along the z direction for forming electrical signal interconnection of the first die 101, the second die 102, the third die 103, and the fourth die 104. The second semiconductor chip 112 and the first semiconductor chip 111 in FIG. 5 may be coupled through the bump 134; and the first connection structure 1011, the first bonding contact 141, the second connection structure 1021, the bump 134, the third connection structure 1031 and the third bonding contact 143 constitute a conductive channel or part of a conductive channel extending along the z direction.

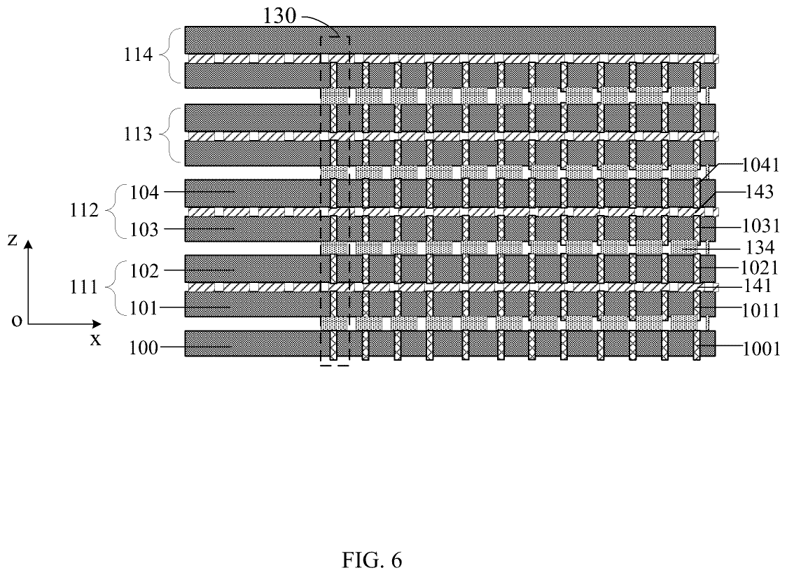

The examples of the present disclosure have no limitation to the number of the semiconductor chips. As an example in FIG. 6, four semiconductor chips are stacked together in the z direction and coupled with each other, and one semiconductor chip may include two bonded dies. For example, the first semiconductor chip 111 may include the first die 101 and the second die 102 that are bonded, and the second semiconductor chip 112 may include the third die 103 and the fourth die 104 that are bonded. Other semiconductor chips, e.g., the third semiconductor chip 113 and the fourth semiconductor chip 114, may be disposed on the second semiconductor chip 112. The topmost die may not be provided with a connection structure, and a connection structure extending through a corresponding die may be disposed under the topmost die.

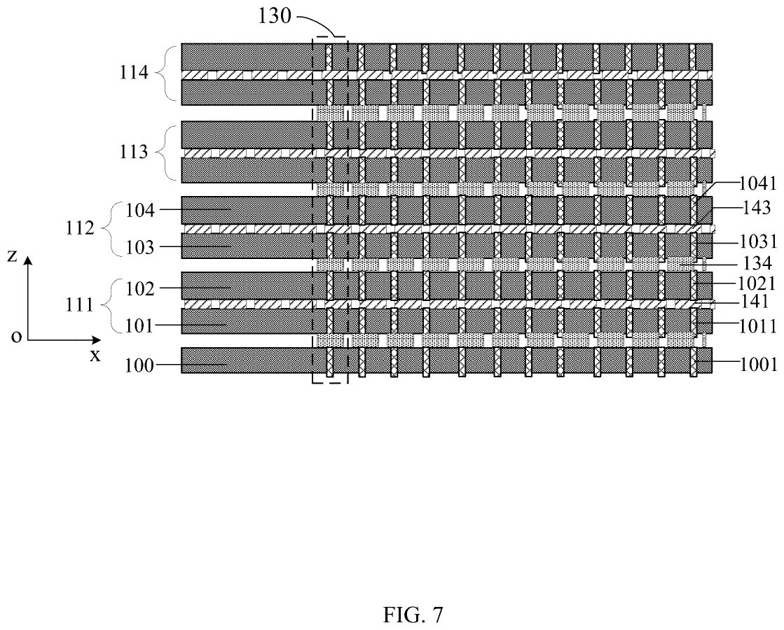

In some examples, with reference to FIG. 6, the second semiconductor chip 112 further includes a fourth connection structure 1041 extending through the fourth die 104 along the z direction. The fourth connection structure 1041 is located on a side of the third bonding contact 143 away from the third connection structure 1031, and is coupled with the third bonding contact 143. With reference to FIG. 7, a connection structure extending through the topmost die may be provided.

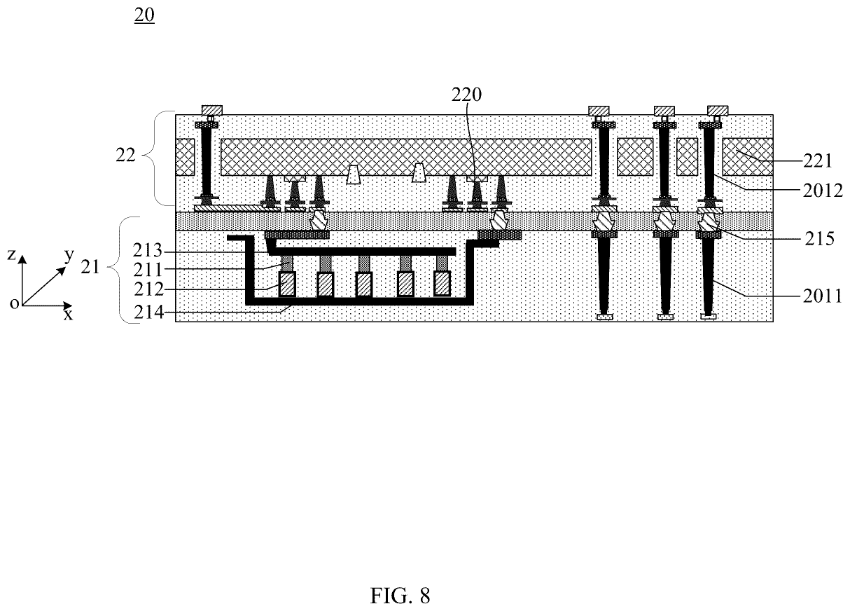

According to some aspects of the examples of the present disclosure, FIG. 8 provides a memory device 20 or a semiconductor structure that may be applied to the semiconductor package structure 10 illustrated in FIGS. 3 to 7. The memory device 20 as shown in FIG. 8 may include a first semiconductor structure 21 and a second semiconductor structure 22 that are hybrid-bonded and coupled in the z direction, and the first semiconductor structure 21 and the second semiconductor structure 22 may be coupled through a bonding contact 215 in FIG. 8. The first semiconductor structure 21 may include a connection structure 2011 extending along the z direction, and the connection structure 2011 may extend through the first semiconductor structure 21 along the z direction and extend through a semiconductor layer 221 and other dielectric layers. The second semiconductor structure 22 may include a connection structure 2012 extending along the z direction, and the connection structure 2012 may extend through the second semiconductor structure 22 along the z direction. The bonding contact 215 is located between the connection structure 2011 and the connection structure 2012, and the bonding contact 215 couples the connection structure 2011 and the connection structure 2012. The first semiconductor structure 21 and the second semiconductor structure 22 may achieve electrical signal interconnection through the connection structure 2011, the bonding contact 215 and the connection structure 2012.

With reference to FIG. 8, the first semiconductor structure 21 may include a DRAM memory array, and may include a transistor 211, a capacitor structure 212 coupled with a first active region of the transistor 211, and a bit line 213 coupled with a second active region of the transistor 211. The first active region or the second active region are one of a source or a drain of the transistor 211, and positions of the source and the drain are interchangeable. The transistor 211 may include a gate layer 2112 that may serve as a word line of the DRAM memory array. The examples of the present disclosure have no limitations to the structure of the transistor 211, which may be a planar transistor and a vertical transistor extending along the z direction. The examples of the present disclosure have no limitations to the structure of the capacitor structure 212, which may include a first electrode, a dielectric layer, and a second electrode. The dielectric layer of the capacitor structure 212 electrically isolates the first electrode and the second electrode, and one electrode of the capacitor structure 212 may extend along the z direction and have a column shape.

The second semiconductor structure 22 may include a peripheral circuit 220 that may include, but is not limited to, a CMOS structure. The CMOS structure may include, but is not limited to, a CMOS transistor or a device or circuit composed of CMOS transistors. Not all device structures of the peripheral circuit 220 are shown in the figure. The peripheral circuit 220 is configured to control the memory array to perform a read, write, or refresh operation. The bit line 213 may be coupled with the bonding contact through at least one of a connection structure or a routing layer to lead out a signal of a second semiconductor sub-structure to achieve electrical signal interconnection with the peripheral circuit 220. The gate layer 2112 and the capacitor structure 212 may lead out the electrical signal through other connection structures respectively and be coupled with the peripheral circuit 220 through the bonding contact 215, to achieve electrical signal interconnection between the memory array and the peripheral circuit 220.

In some examples, in FIG. 8, the transistor 211 may include a semiconductor pillar 2111 extending along the z direction. The first active region and the second active region are located at two opposite ends of the semiconductor pillar 2111 along the z direction respectively; and the capacitor structure 212, the semiconductor pillar 2111, the bit line 213, the bonding contact 215, and the second semiconductor structure 22 are arranged sequentially along the z direction.

In some examples, the first die 101 includes: a transistor 211 including a first active region, a second active region and a gate layer 2112; a bit line 213 coupled with the first active region; a capacitor structure 212 coupled with the second active region; and a peripheral circuit 220 coupled with the bit line 213 and the gate layer 2112.

The first die 101 may include the memory device 20 illustrated in FIG. 8, which may include the first semiconductor structure 21 and the second semiconductor structure 22 that are bonded and coupled in the z direction. The second die 102 may include the memory device 20 as shown in FIG. 8. The first die 101 and the second die 102 may be coupled through hybrid bonding. For example, the second semiconductor structure 22 of the second die 102 is coupled with the first semiconductor structure 21 of the first die 101 through hybrid bonding. For the first die 101, the first connection structure 1011 extending through the first die 101 may include the connection structure 2011, the bonding contact 215 and the connection structure 2012 in FIG. 8. In some examples, when the memory device in FIG. 8 is located at the topmost die, there may be no connection structure 2011 and no connection structure 2012.

In some examples, the first die 101 includes: a transistor 211 including a first active region, a second active region and a gate layer 2112; a bit line 213 coupled with the first active region; and a capacitor structure 212 coupled with the second active region. The second die 102 includes a peripheral circuit 220 coupled with the bit line 213 and the gate layer 2112.

The first die 101 may include the first semiconductor structure 21 in FIG. 8, and the second die 102 may include the second semiconductor structure 22 in FIG. 8.

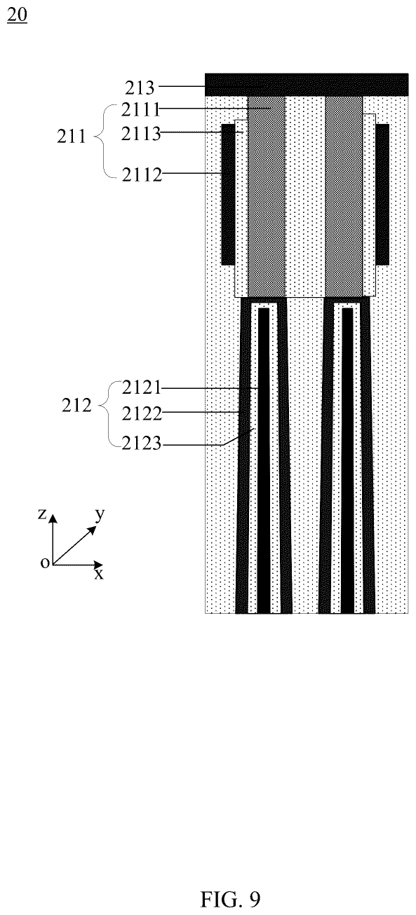

In some examples, with reference to FIG. 9, the transistor 211 includes a semiconductor pillar 2111 extending along the z direction. The first active region and the second active region are located at two opposite ends of the semiconductor pillar 2111 in the z direction, and the gate layer 2112 extends along a direction intersecting the z direction, e.g., along the y direction, and covers part of a sidewall of the semiconductor pillar 2111.

With reference to a partially enlarged view of the transistor 211 and the capacitor structure 212 illustrated in FIG. 9, the semiconductor pillar 2111 extends along the z direction, and a cross sectional shape of the semiconductor pillar 2111 in the xy plane may include a rectangle, other quadrangles, or other regular and irregular polygons, and may include a circle, an ellipse or other irregular curved shapes. The semiconductor pillar 2111 has two ends that are opposite in the z direction, i.e., the first active region and the second active region respectively. The first active region is an upper end of the semiconductor pillar 2111 in a positive z direction in FIG. 9, and is coupled with the bit line 213. The second active region is a lower end of the semiconductor pillar 2111 in a negative z direction, and is coupled with one electrode of the capacitor structure 212. A dielectric material may be filled between adjacent semiconductor pillars 2111, and may have an air gap.

The first active region and the second active region of the semiconductor pillar 2111 may have the same doping type, and an intermediate region between the first active region and the second active region may have a doping type opposite to the first active region as a channel of the transistor 211. The transistor 211 further includes a gate dielectric layer 2113 at least covering the channel of the transistor 211 along the x direction. The gate dielectric layer 2113 covers a sidewall of the semiconductor pillar 2111 in the x direction. The gate layer 2112 covers the gate dielectric layer 2113, and the gate layer 2112 may serve as a control gate of the transistor 211 to which a voltage is applied to control on and off of the transistor 211. The gate layer 2112 may extend along the y direction and may serve as a word line. One gate layer 2112 may correspond to a plurality of semiconductor pillars 2111 arranged in the y direction. The bit line 213 extends along the x direction, and one bit line 213 may correspond to a plurality of semiconductor pillars 2111 arranged in the x direction. The semiconductor pillar 2111 corresponding to both the gate layer 2112 and the bit line 213 may be selected by selecting the gate layer 2112 and the bit line 213, such that the semiconductor pillar 2111 is turned on to select the capacitor structure 212, and operations such as write, refresh or read, etc. are performed by charging and discharging the capacitor structure 212 or sensing the amount of charges of the capacitor structure 212.

In some examples, with continued reference to FIG. 9, the capacitor structure 212 may include a first electrode 2121 extending along the z direction, a dielectric layer 2123 surrounding the first electrode 2121, and a second electrode 2122 surrounding the dielectric layer 2123. The dielectric layer 2123 is located between the first electrode 2121 and the second electrode 2122, and the second electrode 2122 is coupled with the second active region of the semiconductor pillar 2111. An end of the capacitor structure 212 away from the semiconductor pillar 2111 in the z direction is greater than or equal to an end of the capacitor structure 212 close to the semiconductor pillar 2111 in the z direction in the x direction. With reference to FIG. 1, the first electrodes 2121 of the plurality of capacitor structures 212 may be coupled to an interconnection layer 214 for grounding or being applied with other operation voltages. Alternatively, the plurality of capacitor structures 212 share the first electrode 2121, an end of the first electrode 2121 away from the semiconductor pillar 2111 has a film layer structure extending along at least one of the x direction or the y direction, the first electrode 2121 is grounded or applied with other operation voltages, and the plurality of capacitor structures 212 share the first electrode 2121 and are applied with a common voltage.

In some examples, a contact may be disposed between the capacitor structure 212 and the semiconductor pillar 2111. The semiconductor pillar 2111 is coupled with the capacitor structure 212 through the contact. The contact may include a metal silicide (e.g., titanium silicide) to reduce contact resistance between the semiconductor pillar 2111 and the capacitor structure 212 and increase adhesion strength. The contact may include a multi-layer structure, a portion of the multi-layer structure close to or in contact with the semiconductor pillar 2111 may include a metal silicide to reduce the contact resistance and increase the adhesion strength, a portion of the multi-layer structure in contact with the capacitor structure 212 may include a metal to improve electrical connection performance.

In an example, composition materials of the gate layer 2112, the first electrode 2121 and the second electrode 2122 may include, but are not limited to, a conductive material such as tungsten, gold, silver, platinum, copper, aluminum, titanium or nickel, etc. In addition to the above-mentioned conductive materials, the bit line 213 may further include a doped semiconductor material, e.g., doped silicon, etc. Composition materials of the dielectric layer 2123 and the gate dielectric layer 2113 may include, but are not limited to, an insulation material such as silicon oxide, silicon nitride, silicon oxynitride, aluminum oxide, etc.

In some examples, with reference to FIGS. 3 to 7, the semiconductor package structure 10 further includes a base semiconductor chip 100 on a side of the first semiconductor chip 111 away from the second semiconductor chip 112. The base semiconductor chip 100 includes a logic control circuit, and an end of the first connection structure 1011 away from the second connection structure 1021 is coupled with the base semiconductor chip 100. The base semiconductor chip 100 may be coupled with the first semiconductor chip 111 through the bump 134, or the base semiconductor chip 100 may be coupled with the first semiconductor chip 111 through hybrid bonding. The base semiconductor chip 100 may have a connection structure extending along the z direction, for example, a base connection structure 1001 extending through the base semiconductor chip 100. The connection structures extending through a logic semiconductor chip and through each die, and the bonding contact located between and coupling the adjacent connection structures in the z direction and the bump 134 constitutes a conductive channel extending along the z direction for forming electrical signal interconnection between the semiconductor chip and each die. The base semiconductor chip 100 may include, but is not limited to, a logic control circuit, an interface control module, an SRAM cache, and other assemblies. The base semiconductor chip 100 may be configured to control the first semiconductor chip 111, the second semiconductor chip 112 and other chips. In FIGS. 6 and 7, the connection structures extending through each die, the bump 134 and the bonding contact constitute a conductive channel 130 extending along the z direction, and the plurality of dies and the base semiconductor chip 100 may achieve electrical signal interconnection through the conductive channel 130.

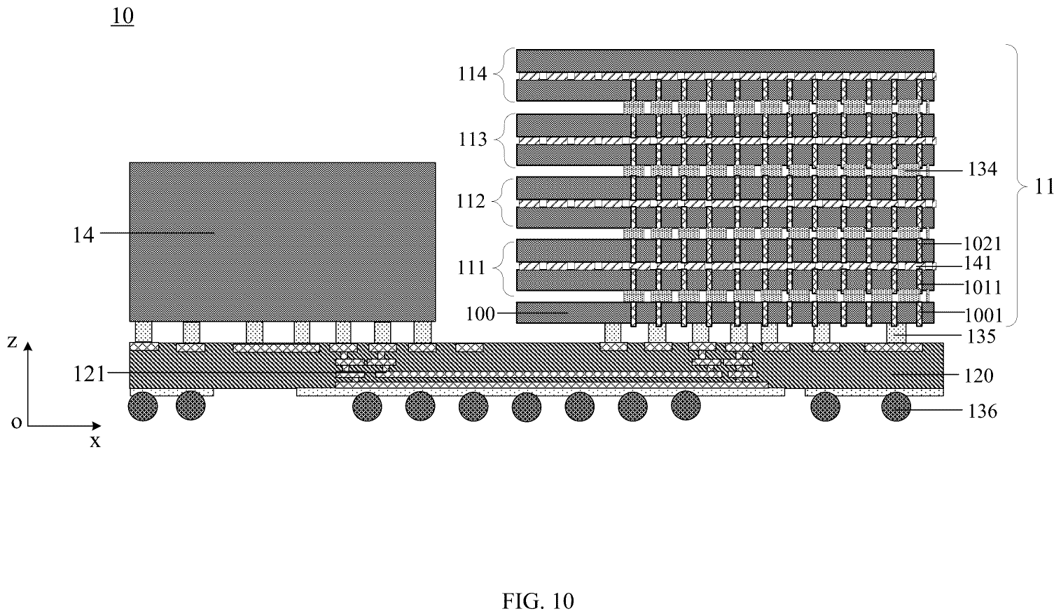

In some examples, with reference to FIG. 10, the semiconductor package structure 10 further includes an interposer substrate 120 on a side of the base semiconductor chip 100 away from the first semiconductor chip 111, and the base semiconductor chip 100 is coupled with the interposer substrate 120. The semiconductor package structure 10 further includes a processor chip 14 located on and coupled with the interposer substrate 120.

The base semiconductor chip 100 is located over and coupled with the interposer substrate 120. The first semiconductor chip 111, the second semiconductor chip 112, or additional semiconductor chips are stacked on the base semiconductor chip 100. The plurality of semiconductor chips stacked sequentially on the base semiconductor chip 100 may constitute a package sub-structure 11. The processor chip 14 and the package sub-structure 11 are located on the interposer substrate 120 and may be coupled with a redistribution layer of the interposer substrate 120 through a bump 135, and the interposer substrate 120 provides power to the processor chip 14 and the package sub-structure 11. Other redistribution layers or interconnection structures are also disposed in the interposer substrate 120, a side of the interposer substrate 120 away from the package sub-structure 11 in the z direction has a contact, and a bump 136 may be disposed to couple with an integrated circuit on an external PCB board.

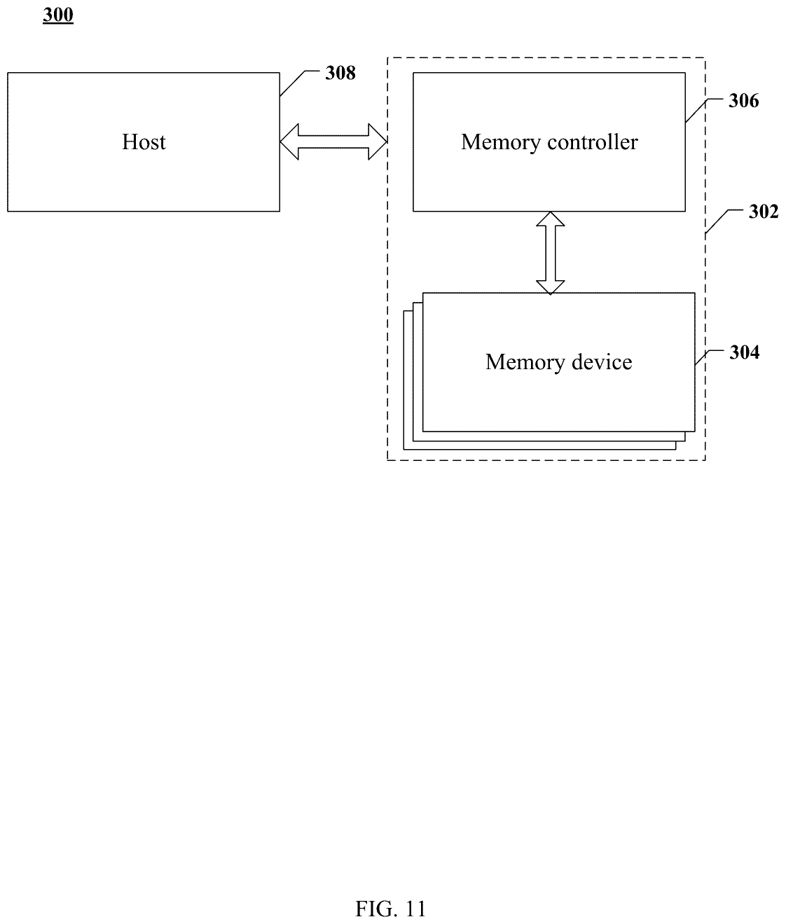

According to some aspects of examples of the present disclosure, a memory system 302 is provided, including a semiconductor package structure 10 illustrated in FIGS. 3 to 7 and 10. FIG. 11 provides a memory system 302 including a memory device 304 and a memory controller 306 coupled with the memory device 304. The memory controller 306 controls the memory device 304 including the semiconductor package structure 10 illustrated in FIGS. 3 to 7, and the semiconductor package structure 10 may be the memory device 304 or at least part of the memory device 304.

With reference to FIG. 11, examples of the present disclosure provide a system 300 including a host 308. The system 300 may be a mobile phone, graphic processing apparatus, desktop computer, laptop computer, tablet computer, vehicle computer, gaming console, printer, positioning apparatus, wearable electronic apparatus, smart sensor, virtual reality (VR) apparatus, augmented reality (AR) apparatus, or any other suitable electronic apparatus having memories therein. As shown in FIG. 11, the system 300 may include the host 308 and the memory system 302, and the memory system 302 has one or more memory devices 304 and the memory controller 306. The host 308 may be a processor (e.g., a central processing unit (CPU)) or a system on chip (SOC) (e.g., an application processor (AP)) of an electronic apparatus. The host 308 may be configured to send or receive data to or from the memory device 304.

According to some examples, the memory controller 306 is coupled to the memory device 304 and the host 308 and is configured to control the memory device 304 to perform read, write, or refresh operations. The memory controller 306 can manage data stored in the memory device 304 and communicate with the host 308. The memory device 304 includes a DRAM or a package structure of a plurality of DRAMs stacked together, and may be applied to an HBM package structure.

In some examples, the HBM package structure may include a plurality of DRAM chips vertically stacked on the base semiconductor chip, and electrical signal interconnection between the base semiconductor chip 100 and the plurality of DRAM chips is achieved through a TSV. The plurality of DRAM chips and the base semiconductor chip 100 may serve as a memory system. The base semiconductor chip 100 may include, but is not limited to, a control logic, an interface control module, an SRAM cache, and other assemblies. The HBM package structure may further include a processor chip 14 such as a GPU, a CPU or an SOC chip. A memory controller may be integrated in the processor to control data transmission of the DRAM chip. In an example, the processor, e.g., such as a GPU, is coupled with the base semiconductor chip 100, and the processor achieves data interaction with the DRAM through the base semiconductor chip 100.

In some other examples, the memory system 302 is applicable to an HBM package product that may include the semiconductor package structure 10 as shown in FIGS. 3 to 7. For example, the base semiconductor chip 100 may be configured as the memory controller 306. A stack structure of the first semiconductor chip 111 and the second semiconductor chip 112 or additional semiconductor chips may be configured as the memory device 304, or the first semiconductor chip 111 and the second semiconductor chip 112 may be configured as the memory devices 304 respectively. The memory system 302 may serve as a memory of the host 308 in the system 300 or a buffer of the system 300.

In some examples, the memory system 302 may be for auxiliary use in a solid-state drive, which can improve performance of reading and writing, etc. of the solid-state drive. Some high-end solid-state drive products generally select embedded DRAMs to improve product performance and to improve the random read-write speeds. In an example, when writing files, especially small files, the small files are stored in a flash after being processed by the DRAMs, such that the solid-state drive has higher storage efficiency and faster speed. The flash includes a non-volatile memory, including, but not limited to, a 2D NAND memory or a 3D NAND memory. In some examples, the memory system 302 may be used as a buffer apparatus of a graphic processing unit (GPU) in a graphic processing apparatus, and the graphic processing apparatus may include, but is not limited to, a graphic card.

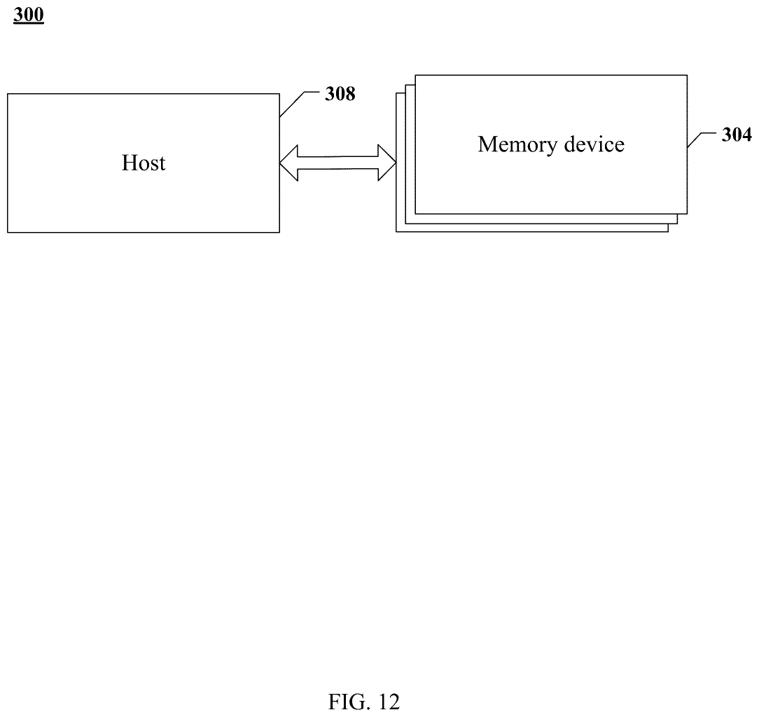

In some other examples, with reference to FIG. 12, the system 300 may only include the host 308 and the memory device 304 coupled with the host 308. A controller that controls the memory device 304 may be a controller inside the host 308, such as a memory controller integrated in a central processing unit (CPU), or a south bridge or north bridge chip integrated in a mainboard of the system 300. The memory device 304 may include, but is not limited to, a double-data-rate synchronous dynamic random access memory in accordance with a DDR4 memory specification or a DDR5 memory specification, and a low-power double-data-rate synchronous dynamic random access memory in accordance with a LPDDR5 memory specification. The memory device 304 may include the semiconductor package structure 10 illustrated in FIGS. 3 to 7.

In some examples, the semiconductor package structure 10 illustrated in FIG. 10 may be applied to an HBM product, and the semiconductor package structure 10 may serve as an electronic apparatus or part of an electronic apparatus. With reference to FIG. 10, the semiconductor package structure 10 may include an interposer substrate 120, a base semiconductor chip 100 on the interposer substrate 120, a plurality of semiconductor chips stacked on the base semiconductor chip 100 along the z direction, and a processor chip 14 on a horizontal side of the base semiconductor chip 100. The logic semiconductor chip and the plurality of semiconductor chips stacked on and coupled with the logic semiconductor chip constitute a package sub-structure 11, and the plurality of semiconductor chips may include the illustrated first semiconductor chip 111, second semiconductor chip 112, third semiconductor chip 113, and fourth semiconductor chip 114, as well as additional semiconductor chips, and the plurality of semiconductor chips may be DRAM chips. By taking the first semiconductor chip 111 as an example, the first semiconductor chip 111 may include a first die 101, a second die 102, or additional dies bonded and coupled in the z direction, and the semiconductor chips may be coupled through a bump 134. Electrical signal interconnection between the dies is achieved through a conductive channel in the z direction, and the conductive channel may include connection structures extending through the dies and a bonding contact and the bump 134 coupling the connection structures.

The base semiconductor chip 100 may be coupled with the interposer substrate 120 through the bump 135 or through hybrid bonding, the semiconductor chip is coupled with the base semiconductor chip through the bump 134, and the processor chip 14 may be coupled with the interposer substrate 120 through the bump 135. The base semiconductor chip 100 may be coupled with the processor chip 14 through the bump 135 and a routing layer 121 of the interposer substrate 120, and the routing layer 121 may be located on and/or in the interposer substrate 120. The routing layer 121 may include, but is not limited to, a redistribution layer composed of wirings and contact plugs, and may include a plurality of interconnect layers that are stacked and coupled with each other. The semiconductor package structure 10 further includes a bump 136 on a side of the interposer substrate 120 away from the semiconductor chip, and the bump 136 may be configured to be coupled with a PCB board so that the semiconductor package structure may access an integrated circuit. The bump 135 and the bump 136 may be coupled through the routing layer 121 in the interposer substrate 120. In an example, the bump 134, the bump 135 and the bump 136 may include, but are not limited to, a solder ball, a conductive ball or a conductive contact.

In some examples, the base semiconductor chip 100 and the plurality of semiconductor chips in FIGS. 3 to 7 may be stacked to form a package sub-structure 11 that achieves electrical signal interconnection with the processor chip 14 through the interposer substrate 120 in FIG. 10. The package sub-structure 11 may be configured as the memory system 302, where the base semiconductor chip 100 may be configured as the memory controller 306 which has a control logic, an interface control module, an SRAM cache and other assemblies. Alternatively, the semiconductor package structure 10 may be configured as the memory system 302, the package sub-structure 11 may be configured as the memory device 304, and the memory controller 306 or at least a control portion of the memory controller 306 is integrated in the processor chip 14, for example, an HBM controller or a memory controller is integrated in the processor chip 14, and the base semiconductor chip 100 is integrated with a power control module and an interface control module.

In some other examples, a processor chip 14 and a plurality of package sub-structures 11 may be integrated on the interposer substrate 120 to form the semiconductor package structure 10, and each package sub-structure 11 may achieve electrical signal interconnection with the processor chip 14 through the bump 135 and the interposer substrate 120.

In some examples, the semiconductor package structure 10 further includes a mold layer covering the package sub-structure 11, the processor chip 14 and the interposer substrate 120 to protect devices. The mold layer may include, but is not limited to, insulation materials such as silicon oxide, epoxy resin, polyurethane, etc. An outer surface of the mold layer may be covered with a conductive layer to shield electromagnetic interference and to dissipate heat, and a heat dissipation lid or a heat spreader may be disposed above the package sub-structure 11 and the processor chip 14 to facilitate heat dissipation.

In some examples provided by the present disclosure, it is to be understood that the disclosed apparatus and method may be implemented in other manners. The apparatus examples described above are illustrative only, for example, the division of units is merely a division for logical functions. In actual implementations, there may be other methods for division. For example, a plurality of units or assemblies may be combined, or may be integrated to another system, or some features may be omitted or not performed. In addition, the various constituent parts as shown or as discussed may be coupled directly or indirectly. The methods disclosed in several method examples provided in the present disclosure may be combined arbitrarily in case of no conflicts, so as to obtain a new method example.

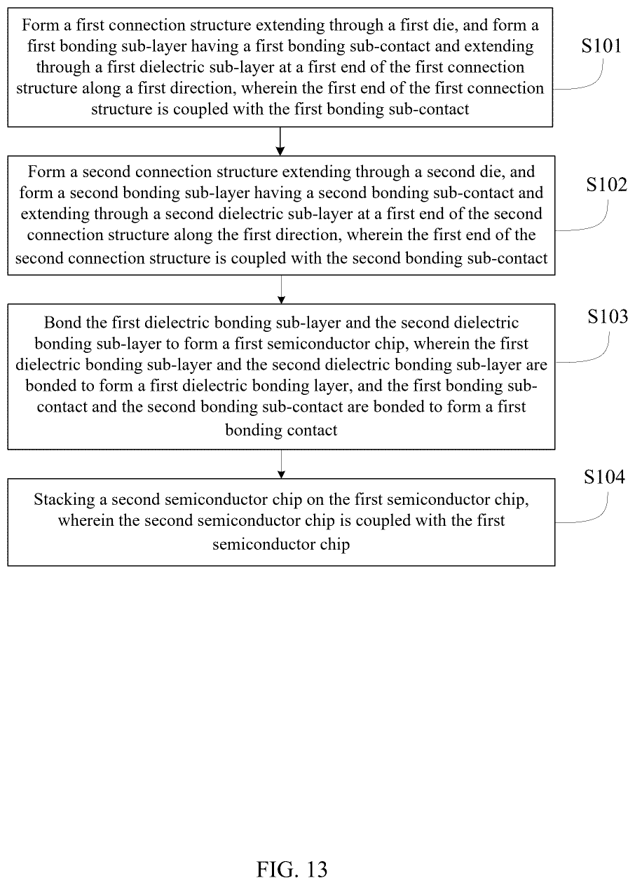

According to some aspects of examples of the present disclosure, FIG. 13 provides a method of fabricating a semiconductor package structure 10. The method may include forming a first connection structure extending through a first die, and forming a first bonding sub-layer having a first bonding sub-contact at a first end of the first connection structure along a first direction, where the first end of the first connection structure is coupled with the first bonding sub-contact. The method may include forming a second connection structure extending through a second die, and forming a second bonding sub-layer having a second bonding sub-contact at a first end of the second connection structure along the first direction, where the first end of the second connection structure is coupled with the second bonding sub-contact. The method may include bonding the first bonding sub-layer and the second bonding sub-layer to form a first semiconductor chip, where the first bonding sub-layer and the second bonding sub-layer are bonded to form a first bonding layer, and the first bonding sub-contact and the second bonding sub-contact are bonded to form a first bonding contact. The method may include stacking a second semiconductor chip on the first semiconductor chip, where the second semiconductor chip is coupled with the first semiconductor chip.

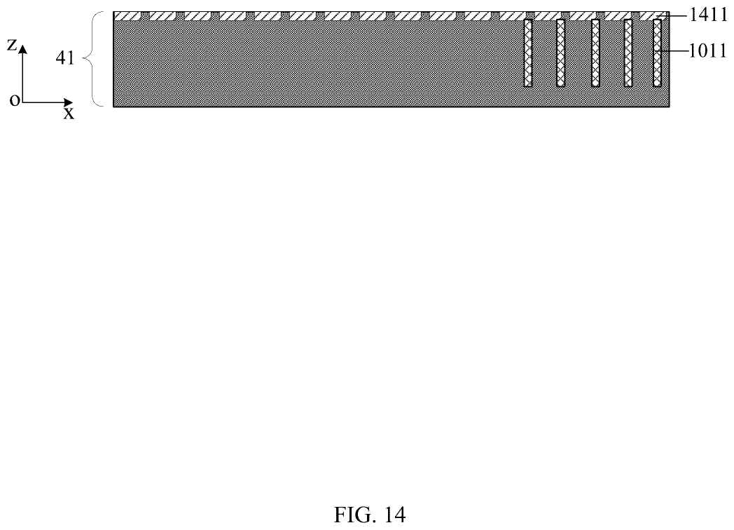

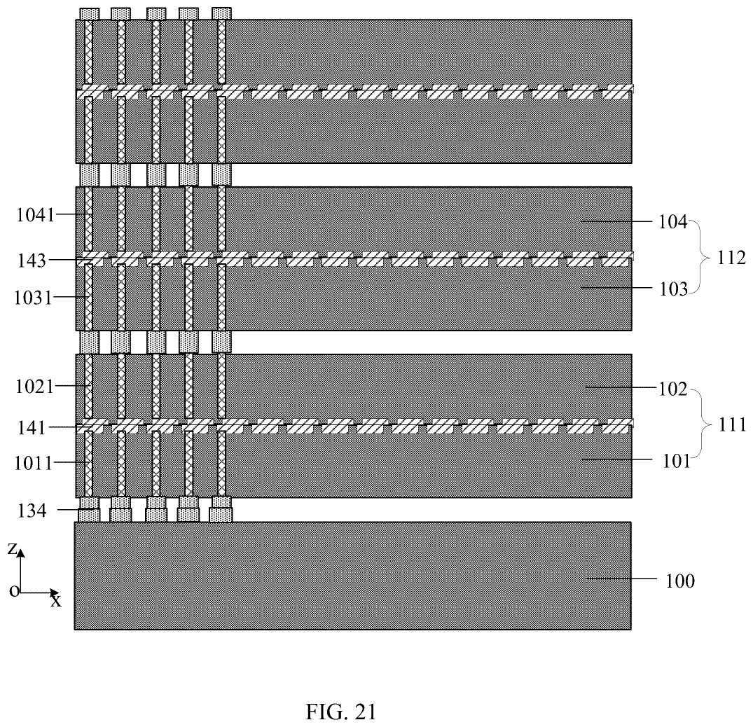

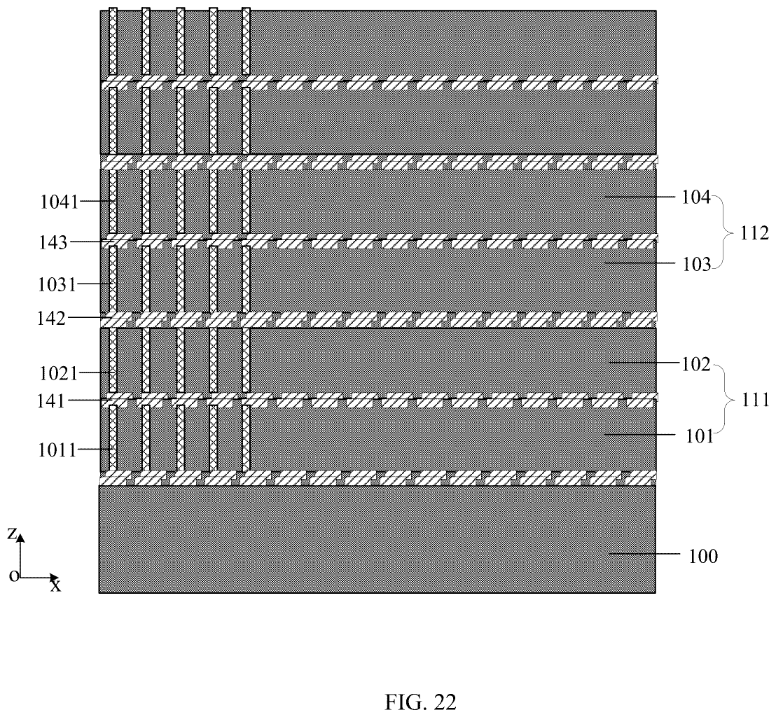

With reference to FIG. 14, the first connection structure 1011 extending along the z direction is formed in the first die 101, and may extend through the first die 101, or the first connection structure 1011 may partially extend through the first die 101. As shown in FIG. 14, the first end of the first connection structure 1011 is exposed from a side of the first die 101, a second end of the first connection structure 1011 opposite to the first end in the z direction is located in the first die 101, and a surface of the first die 101 is thinned subsequently to expose the second end of the first connection structure 1011. The structure in FIG. 14 may be a first wafer 41 including the first dies 101. The first wafer 41 may include a plurality of first dies 101, one first die 101 may correspond to a plurality of first connection structures 1011, the plurality of first dies 101 may be formed after cutting the first wafer 41, and the first die 101 may be referred to FIGS. 21 and 22 below.

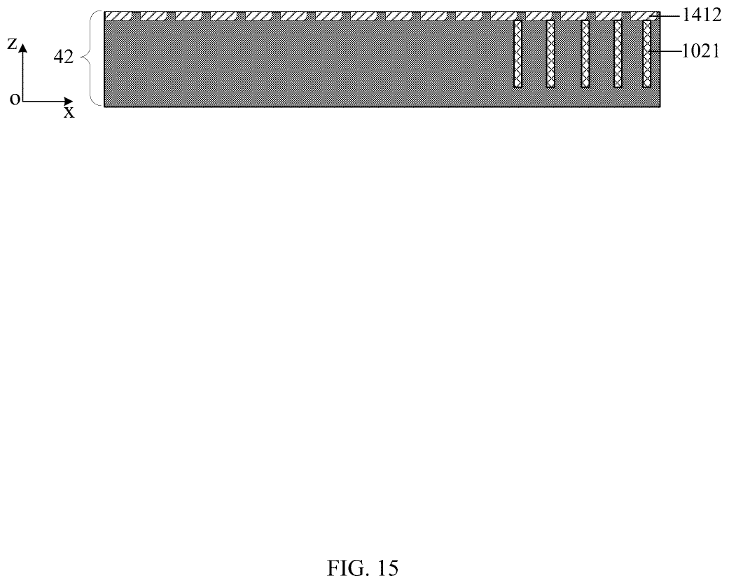

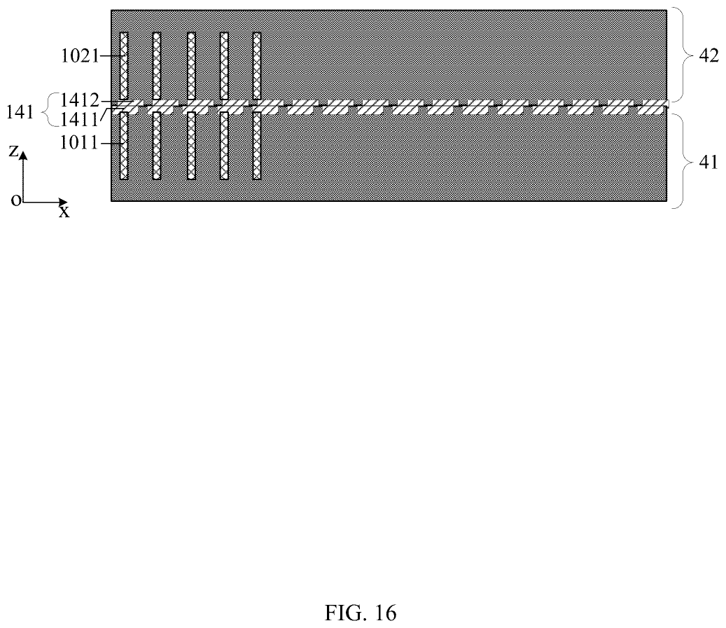

With reference to FIG. 15, the second connection structure 1021 extending along the z direction is formed in the second die 102, and the first end of the second connection structure 1021 is exposed from a side of the second die 102. The first bonding sub-layer having the plurality of first bonding sub-contacts 1411 is formed on the first end of the first connection structure 1011, and the second bonding sub-layer having the plurality of second bonding sub-contacts 1412 is formed on the first end of the second connection structure 1021. The first bonding sub-layer and the second bonding sub-layer are bonded, the first bonding sub-contact 1411 and the second bonding sub-contact 1412 are coupled after bonding, and the first die 101 and the second die 102 are coupled to form the first semiconductor chip 111. The first bonding sub-layer includes a first bonding sub-contact 1411 and a first dielectric sub-layer, and the second bonding sub-layer may include a second bonding sub-contact 1412 and a second dielectric sub-layer. The first dielectric sub-layer and the second dielectric sub-layer may not have a physical boundary after thermal compression bonding, and the first bonding sub-contact 1411 and the second bonding sub-contact 1412 may not have a physical boundary after bonding, so as to form the first bonding contact 141 as shown in FIG. 16.

In some examples, the method may include forming a bump 134 at an end of the second connection structure 1021 away from the first connection structure 1011, where the bump 134 is coupled with the second connection structure 1021; and the method may include stacking the second semiconductor chip 112 on the bump 134, where the second semiconductor chip 112 is coupled with the first semiconductor chip 111 through the bump 134.

With reference to FIG. 21 below, the second semiconductor chip 112 or additional semiconductor chips are stacked together on a side of the second die 102 away from the first die 101, the semiconductor chips are connected through the bump 134, and the dies in the same semiconductor chip are coupled through hybrid bonding. The topmost semiconductor chip in the package structure may not be provided with a connection structure extending through the topmost die, or may be provided with a connection structure extending through the topmost die. A formation process of the bump 134 may include, but is not limited to, reflow soldering. The first semiconductor chip 111 may be coupled with the second semiconductor chip 112 through hybrid bonding.

In some examples, with reference to FIG. 22, the method may include bonding the second semiconductor chip 112 on a side of the second connection structure 1021 away from the first connection structure 1011, where the first semiconductor chip 111 is coupled with the second semiconductor chip 112 through a second bonding contact 142, and the second bonding contact 142 is located at an end of the second connection structure 1021 away from the first connection structure 1011 and is coupled with the second connection structure 1021.

In some examples, with reference to FIG. 14, the first wafer 41 includes the first die 101, the first end of the first connection structure 1011 is exposed from a surface of the first wafer 41, and the second end of the first connection structure 1011 opposite to the first end in the z direction is located in the first wafer 41. With reference to FIG. 15, a second wafer 42 includes the second die 102, the first end of the second connection structure 1021 is exposed from a surface of the second wafer 42, and a second end of the second connection structure 1021 along the z direction is located in the second wafer 42. A method of fabricating the first semiconductor chip 111 includes forming the first bonding sub-layer on a side of the first wafer 41 exposing the first connection structure 1011; the method of fabricating the first semiconductor chip 111 includes forming the second bonding sub-layer on a side of the second wafer 42 exposing the second connection structure 1021. With reference to FIG. 16, bonding the first bonding sub-layer and the second bonding sub-layer may be performed such that the first bonding sub-contact 1411 and the second bonding sub-contact 1412 are bonded and coupled with each other. The first bonding sub-contact 1411 and the second bonding sub-contact 1412 may not have a physical boundary after bonding, so as to form the first bonding contact 141. In FIG. 16, the second wafer 42 is located over the first die 41.

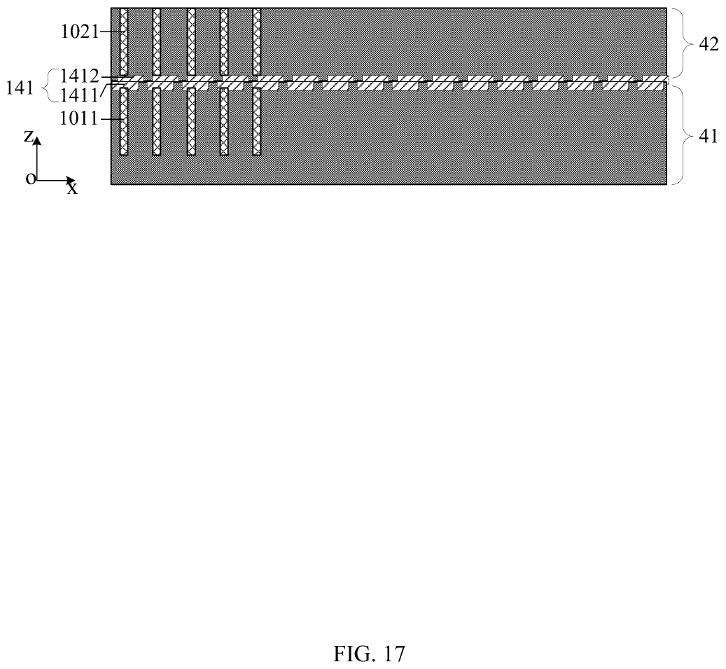

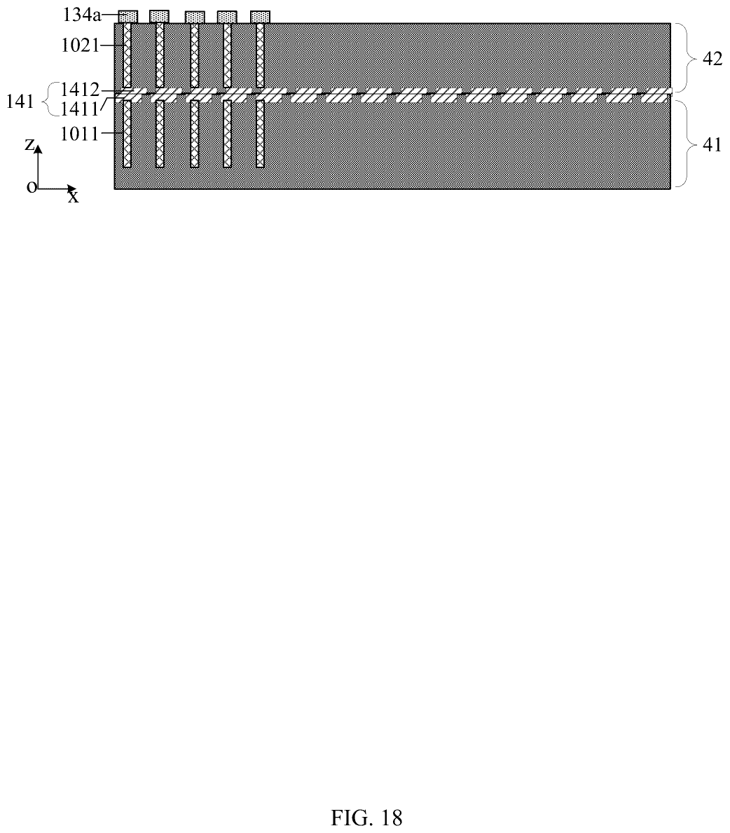

In some examples, the method of fabricating the first semiconductor chip 111 further includes, with reference to FIG. 17, thinning the second wafer 42 to expose the second end of the second connection structure 1021; and with reference to FIG. 18, the method of fabricating the first semiconductor chip 111 forming a first bump 134a on the second end of the second connection structure 1021, where the first bump 134a is coupled with the second end of the second connection structure 1021. The thinned surface of the second wafer 42 is a side of the second wafer 42 away from the bonding interface to expose the second connection structure 1021, such that the second connection structure 1021 extends through the second wafer 42 (or extends through the second die 102) along the z direction. The thinning process may include, but is not limited to, etching, chemical mechanical polishing or a combination thereof.

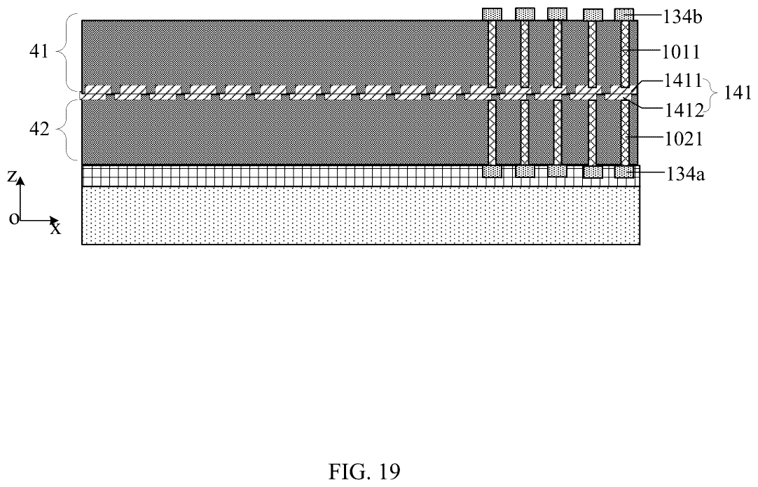

In some examples, the method of fabricating the first semiconductor chip 111 further includes, with reference to FIG. 19, bonding a carrier wafer and the second wafer 42, and turning over the structure with the carrier wafer as a support; the method of fabricating the first semiconductor chip 111 further include thinning the first wafer 41 to expose the second end of the first connection structure 1011; the method of fabricating the first semiconductor chip 111 further include forming a second bump 134b on the second end of the first connection structure 1011, where the second bump 134b is coupled with the second end of the first connection structure 1011; and the method of fabricating the first semiconductor chip 111 further include cutting a bonded structure of the first wafer 41 and the second wafer 42 to obtain a plurality of first semiconductor chips 111. The carrier wafer is bonded with the second wafer 42 through a bonding adhesive, the first bump 134a may be in contact with the bonding adhesive, and the bonding adhesive protects the first bump 134a to reduce damage of the first bump 134a.

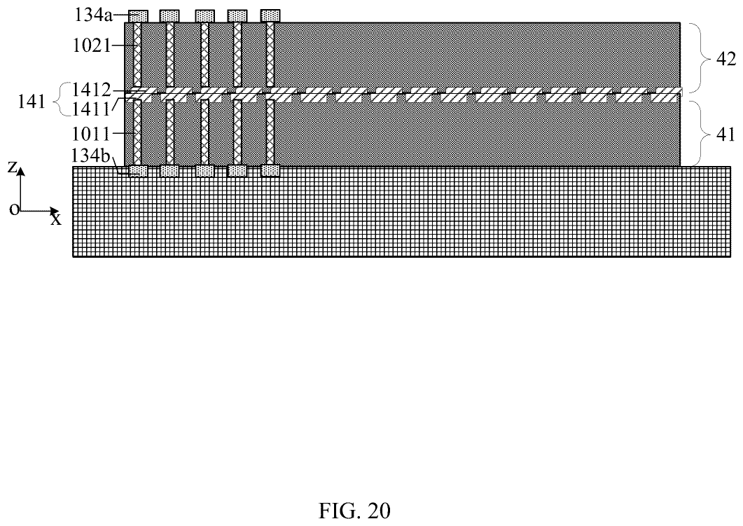

With reference to FIG. 20, a side of the first wafer 41 in FIG. 19 having the second bump 134b is adhered to a carrier film to protect the second bump 134b, and the second wafer 42 and the first wafer 41 are cut along cutting lanes of the second wafer 42 and the first wafer 41 to form the bonded first die 101 and second die 102 that constitute the first semiconductor chip 111. During bonding of the first wafer 41 and the second wafer 42, the first bonding sub-contact 1411 of the first wafer 41 and the second bonding sub-contact 1412 of the second wafer 42 are aligned and bonded with each other, and the cutting lane of the first wafer 41 is aligned with the cutting lane of the second wafer 42 in the z direction.

In some examples, the bonded structure of the first wafer 41 and the second wafer 42 of FIG. 20 may be cut to form a plurality of semiconductor chips, and one semiconductor chip includes the first die 101 and the second die 102 that are hybrid-bonded. Tests such as electrical test and aging test, etc. are performed on the semiconductor chips. The semiconductor chips with satisfying yield and stability parameters are stacked on the base semiconductor chip 100 as shown in FIG. 21. A bump 134 is disposed between the semiconductor chips, and the bump 134 is coupled with a connection structure to achieve electrical signal interconnection between the semiconductor chips. The semiconductor chips may be stacked on a wafer including the base semiconductor chip 100, and the semiconductor chips are coupled thorough the bump 134; and afterwards, the semiconductor package structure 10 is formed after cutting. As illustrated in FIG. 21, the first semiconductor chip 111, the second semiconductor chip 112, and additional semiconductor chips are stacked sequentially on the base semiconductor chip 100, and have connection structures extending through the dies therein. “First” and “Second” are used to distinguish different chips. The first semiconductor chip 111 and the second semiconductor chip 112 may be obtained from the plurality of chips after cutting the bonded structure in FIG. 20.

In some other examples, with reference to FIG. 22, the plurality of semiconductor chips are sequentially bonded on the base semiconductor chip 100 or the wafer including the base semiconductor chip 100, and are coupled through the bonding contact. For example, the second semiconductor chip 112 and the first semiconductor chip 111 are bonded and coupled through the second bonding contact 142.

In some examples, a method of fabricating the second semiconductor chip 112 includes forming a third connection structure 1031 extending through a third die 103 along the z direction; and with reference to FIG. 21, the method of fabricating the second semiconductor chip 112 includes bonding the third die 103 and a fourth die 104 along the z direction to form the second semiconductor chip 112, where the third die 103 is located between the second die 102 and the fourth die 104 and is coupled with the fourth die 104 through a third bonding contact 143, and the third connection structure 1031 is located between the second connection structure 1021 and the third bonding contact 143 and is coupled with the second connection structure 1021 and the third bonding contact 143. In some examples, the method of fabricating further includes forming a fourth connection structure 1041 extending through a fourth die 104 along the z direction, where the fourth connection structure 1041 is coupled with the third connection structure 1031 through the third bonding contact 143.

In some other examples, with reference to FIGS. 4 to 6, after the plurality of semiconductor chips are stacked together, the topmost die may not be provided with a connection structure extending through the die. For example, only the first semiconductor chip 111 and the second semiconductor chip 112 are stacked together, and the second semiconductor chip 112 may not be provided with the fourth connection structure 1041 extending through the fourth die 104.

In some examples, a method of fabricating the first die 101 includes, with reference to FIG. 8, forming a transistor 211 including a first active region, a second active region and a gate layer 2112; the method of fabricating the first die 101 includes forming a bit line 213 coupled with the first active region; the method of fabricating the first die 101 includes forming a capacitor structure 212 coupled with the second active region; and the method of fabricating the first die 101 includes forming a peripheral circuit 220 coupled with the bit line 213 and the gate layer 2112. The first die 101 may include the first semiconductor structure 21 and the second semiconductor structure 22 as shown in FIG. 8. The first semiconductor structure 21 is coupled with the second semiconductor structure 22 through a bonding contact 215, and a connection structure 2011 of the first semiconductor structure 21 is coupled with a connection structure 2012 of the second semiconductor structure 22 through the bonding contact 215. The second die 102 may include the memory device 20 as shown in FIG. 8, and the first die 101 may be coupled with the second die 102 through hybrid bonding.

In some examples, a method of fabricating the first die 101 includes, with reference to FIG. 8, forming a transistor 211 including a first active region, a second active region and a gate layer 2112; the method of fabricating the first die 101 includes forming a bit line 213 coupled with the first active region; and the method of fabricating the first die 101 includes forming a capacitor structure 212 coupled with the second active region. A method of fabricating the second die 102 includes forming a peripheral circuit 220 coupled with the bit line 213 and the gate layer 2112.

The first die 101 may include the first semiconductor structure 21 as shown in FIG. 8, and the second die 102 may include the second semiconductor structure 22 as shown in FIG. 8.

In some examples, the method of fabricating may include, with reference to FIGS. 21 and 22, disposing the first semiconductor chip 111 on the base semiconductor chip 100. The base semiconductor chip 100 includes a logic control circuit, and an end of the first connection structure 1011 away from the second connection structure 1021 is coupled with the base semiconductor chip 100. A base connection structure 1001 extending through the base semiconductor chip 100 is also formed, and the base connection structure 1001 is coupled with the first connection structure 1011 through hybrid bonding or the bump 134.

In some examples, the method of fabricating further includes, with reference to FIG. 10, disposing the base semiconductor chip 100 on an interposer substrate 120, and the base semiconductor chip 100 is coupled with the interposer substrate 120. A processor chip 14 is disposed on and coupled with the interposer substrate 120.

The base semiconductor chip 100 is located over and coupled with the interposer substrate 120, and the first semiconductor chip 111, the second semiconductor chip 112 or additional semiconductor chips are stacked together on the base semiconductor chip 100. The plurality of semiconductor chips stacked sequentially on the base semiconductor chip 100 may constitute a package sub-structure 11. The processor chip 14 and the package sub-structure 11 are located on the interposer substrate 120 and may be coupled with a redistribution layer of the interposer substrate 120 through a bump 135, and the interposer substrate 120 provides power and signal interaction for the processor chip 14 and the package sub-structure 11. Other redistribution layers or interconnection structures are further disposed in the interposer substrate 120, and a side of the interposer substrate 120 away from the package sub-structure 11 in the z direction has a contact, and a bump 136 may be disposed to couple with an integrated circuit on an external PCB board.

In some examples, a mold layer covering the package sub-structure 11 and the processor chip 14 is formed on the semiconductor package structure 10 illustrated in FIG. 10, an outer surface of the mold layer may be covered with a conductive layer to shield electromagnetic interference and to dissipate heat, and a heat dissipation lid or a heat spreader may be disposed over the package sub-structure 11 and the processor chip 14 to facilitate heat dissipation.

The above descriptions are merely specific implementations of the present disclosure, and the protection scope of the present disclosure is not limited thereto. Any variation or replacement that may be readily figured out by those skilled in the art within the technical scope disclosed by the present disclosure should fall within the protection scope of the present disclosure.

What is claimed is:

1. A semiconductor package structure, comprising:
a first semiconductor chip and a second semiconductor chip stacked along a first direction and coupled with each other, wherein the first semiconductor chip comprises a first die and a second die that are bonded along the first direction, and the first die is coupled with the second die through a first bonding contact;
a first connection structure extending through the first die along the first direction; and
a second connection structure extending through the second die along the first direction, wherein the first bonding contact is located between the first connection structure and the second connection structure in the first direction, and the first connection structure is coupled with the second connection structure through the first bonding contact.

2. The semiconductor package structure of claim 1, comprising:
a bump that is located at an end of the second connection structure away from the first connection structure and is located between the second connection structure and the second semiconductor chip, wherein the first semiconductor chip and the second semiconductor chip are coupled at least through the bump and the second connection structure.

3. The semiconductor package structure of claim 1, wherein the first semiconductor chip is bonded with the second semiconductor chip, the first semiconductor chip and the second semiconductor chip are coupled through a second bonding contact, and the second bonding contact is located at an end of the second connection structure away from the first connection structure and is coupled with the second connection structure.

4. The semiconductor package structure of claim 1, wherein the second semiconductor chip comprises:
a third die and a fourth die that are bonded along the first direction, wherein the third die is located between the second die and the fourth die, and the third die and the fourth die are coupled through a third bonding contact; and
a third connection structure extending through the third die along the first direction, wherein the third connection structure is located between the second connection structure and the third bonding contact and is coupled with the second connection structure and the third bonding contact.

5. The semiconductor package structure of claim 4, wherein the second semiconductor chip further comprises:
a fourth connection structure extending through the fourth die along the first direction, wherein the fourth connection structure is located on a side of the third bonding contact away from the third connection structure and is coupled with the third bonding contact.

6. The semiconductor package structure of claim 1, wherein the first die comprises:
a transistor comprising a first active region, a second active region, and a gate layer;
a bit line coupled with the first active region;
a capacitor structure coupled with the second active region; and
a peripheral circuit coupled with the bit line and the gate layer.

7. The semiconductor package structure of claim 1, wherein
the first die comprises:
a transistor comprising a first active region, a second active region and a gate layer;
a bit line coupled with the first active region; and
a capacitor structure coupled with the second active region; and
the second die comprises:
a peripheral circuit coupled with the bit line and the gate layer.

8. The semiconductor package structure of claim 6, wherein the transistor comprises:
a semiconductor pillar extending along the first direction, wherein the first active region and the second active region are located at two opposite ends of the semiconductor pillar in the first direction, and wherein the gate layer extends along a direction intersecting the first direction, and covers part of a sidewall of the semiconductor pillar.

9. The semiconductor package structure of claim 1, further comprising:
a base semiconductor chip located on a side of the first semiconductor chip away from the second semiconductor chip and comprising a logic control circuit, wherein an end of the first connection structure away from the second connection structure is coupled with the base semiconductor chip.

10. The semiconductor package structure of claim 9, further comprising:
an interposer substrate located on a side of the base semiconductor chip away from the first semiconductor chip, wherein the base semiconductor chip is coupled with the interposer substrate.

11. A method of fabricating a semiconductor package structure, comprising:
forming a first connection structure extending through a first die, and forming a first bonding sub-layer having a first bonding sub-contact at a first end of the first connection structure along a first direction, wherein the first end of the first connection structure is coupled with the first bonding sub-contact;
forming a second connection structure extending through a second die, and forming a second bonding sub-layer having a second bonding sub-contact at a first end of the second connection structure along the first direction, wherein the first end of the second connection structure is coupled with the second bonding sub-contact;
bonding the first bonding sub-layer and the second bonding sub-layer to form a first semiconductor chip, wherein the first bonding sub-layer and the second bonding sub-layer are bonded to form a first bonding layer, and the first bonding sub-contact and the second bonding sub-contact are bonded to form a first bonding contact; and
stacking a second semiconductor chip on the first semiconductor chip, wherein the second semiconductor chip is coupled with the first semiconductor chip.

12. The method of claim 11, comprising:
forming a bump at an end of the second connection structure away from the first connection structure, wherein the bump is coupled with the second connection structure; and
stacking the second semiconductor chip on the bump, wherein the second semiconductor chip is coupled with the first semiconductor chip through the bump.

13. The method of claim 11, comprising:
bonding the second semiconductor chip on a side of the second connection structure away from the first connection structure, wherein the first semiconductor chip is coupled with the second semiconductor chip through a second bonding contact, and the second bonding contact is located at an end of the second connection structure away from the first connection structure and is coupled with the second connection structure.

14. The method of claim 11, wherein:
a first wafer comprises the first die, the first end of the first connection structure is exposed from a surface of the first wafer, and a second end of the first connection structure opposite to the first end in the first direction is located in the first wafer;
a second wafer comprises the second die, the first end of the second connection structure is exposed from a surface of the second wafer, and a second end of the second connection structure along the first direction is located in the second wafer; and
forming the first semiconductor chip comprises:
forming the first bonding sub-layer on a side of the first wafer exposing the first connection structure;
forming the second bonding sub-layer on a side of the second wafer exposing the second connection structure; and
bonding the first bonding sub-layer and the second bonding sub-layer, wherein the first bonding sub-contact is coupled with the second bonding sub-contact.

15. The method of claim 14, wherein forming the first semiconductor chip further comprises:
thinning the second wafer to expose the second end of the second connection structure; and
forming a first bump on the second end of the second connection structure, wherein the first bump is coupled with the second end of the second connection structure.

16. The method of claim 15, wherein forming the first semiconductor chip further comprises:
thinning the first wafer to expose the second end of the first connection structure;
forming a second bump on the second end of the first connection structure, wherein the second bump is coupled with the second end of the first connection structure; and
cutting a bonded structure of the first wafer and the second wafer to obtain a plurality of first semiconductor chips.

17. The method of claim 11, wherein forming the second semiconductor chip comprises:
forming a third connection structure extending through a third die along the first direction; and
bonding the third die and a fourth die along the first direction to form the second semiconductor chip, wherein the third die is located between the second die and the fourth die and is coupled with the fourth die through a third bonding contact, and the third connection structure is located between the second connection structure and the third bonding contact and is coupled with the second connection structure and the third bonding contact.

18. The method of claim 17, further comprising:
forming a fourth connection structure extending through the fourth die along the first direction, wherein the fourth connection structure is coupled with the third connection structure through the third bonding contact.

19. The method of claim 11, wherein forming the first die comprises:
forming a transistor comprising a first active region, a second active region, and a gate layer;
forming a bit line coupled with the first active region;
forming a capacitor structure coupled with the second active region; and
forming a peripheral circuit coupled with the bit line and the gate layer.

20. A memory system, comprising:
a semiconductor package structure, comprising:
a first semiconductor chip and a second semiconductor chip stacked along a first direction and coupled with each other, wherein the first semiconductor chip comprises a first die and a second die that are bonded along the first direction, and the first die is coupled with the second die through a first bonding contact;
a first connection structure extending through the first die along the first direction; and
a second connection structure extending through the second die along the first direction, wherein the first bonding contact is located between the first connection structure and the second connection structure in the first direction, and the first connection structure is coupled with the second connection structure through the first bonding contact.
